(19) United States
(12) Patent Application Publication
(10) Pub. No.: US 2026/0362891 A1
(43) Pub. Date: Nov. 12, 2026

(54) METHODS FOR PREPARING PEROVSKITE SOLAR CELLS (PSCS) AND THE RESULTING PSCS

(71) Applicants: UNIVERSITY OF LOUISVILLE RESEARCH FOUNDATION, INC., Louisville, KY (US); ALLIANCE FOR ENERGY INNOVATION, LLC, Golden, CO (US)

(72) Inventors: Thad DRUFFEL, Louisville, KY (US); Craig A. GRAPPERHAUS, Jeffersonville, IN (US); Sashil CHAPAGAIN, Louisville, KY (US); Peter James ARMSTRONG, Louisville, KY (US); Blake MARTIN, Louisville, KY (US); Marinus Franciscus Antonius Maria VAN HEST, Golden, CO (US)

(73) Assignees: UNIVERSITY OF LOUISVILLE RESEARCH FOUNDATION, INC., Louisville, KY (US); ALLIANCE FOR ENERGY INNOVATION, LLC, Golden, CO (US)

(21) Appl. No.: 19/745,128

(22) Filed: Jul. 17, 2026

Related U.S. Application Data
(63) Continuation of application No. 18/692,995, filed on Sep. 20, 2022.
(60) Provisional application No. 63/261,441, filed on Sep. 21, 2021.

(51) Int. Cl. H10K 30/40; C01G 19/02; C01G 21/16; C01G 53/04; C01G 53/40

(52) U.S. Cl. CPC H10K 30/40; C01G 19/02; C01G 21/16; C01G 53/04; C01G 53/40; C01P 2002/34; C01P 2002/50; C01P 2002/72; C01P 2002/82; C01P 2002/84; C01P 2002/85; C01P 2002/88; C01P 2004/03

(57) ABSTRACT

Some embodiments of the invention include inventive methods for preparing perovskite solar cells (PSCs). In certain embodiments, the method comprises dissolving a functionalized material (e.g., a material that is functionalized with one or more functionalizing compounds) in a solvent, depositing a deposit composition on a perovskite layer where the deposit composition comprises the dissolved functionalized material, heating the deposit composition, and optionally removing some or all of the one or more functionalizing compounds from the deposit composition. Additional embodiments of the invention are also disclosed herein.

### CROSS-REFERENCE TO RELATED APPLICATIONS

This application claims the benefit of U.S. Provisional Application No. 63/261,441, filed Sep. 21, 2021 entitled “Solar cells, methods for making, and methods for using” which is herein incorporated by reference in its entirety.

### GOVERNMENT RIGHTS

This invention was made with government support under DE-EE0008752 awarded by the Department of Energy. The government has certain rights in the invention.

### BACKGROUND

Several perovskite solar cells (PSCs) are known. However, the methods for making PSCs have limitations, such as but not limited to solvent incompatibility, processing temperature etc., which can sometimes result in damage to the perovskite layer.

Certain embodiments of the invention address one or more of the deficiencies described above. Some embodiments of the invention include inventive methods for preparing perovskite solar cells (PSCs). In certain embodiments, the method comprises dissolving a functionalized material (e.g., a material that is functionalized with one or more functionalizing compounds) in a solvent, depositing a deposit composition on a perovskite layer where the deposit composition comprises the dissolved functionalized material, heating the deposit composition, and optionally removing some or all of the one or more functionalizing compounds from the deposit composition. Additional embodiments of the invention are also disclosed herein.

### SUMMARY

Some embodiments of the present invention include methods for preparing a Perovskite Solar Cell (PSC), the method comprising: dissolving a functionalized material in a solvent, where the functionalized material is a material that is functionalized with one or more functionalizing compounds; depositing a deposit composition on a perovskite layer, where the deposit composition comprises the dissolved functionalized material; heating the deposit composition; and optionally removing some or all of the one or more functionalizing compounds from the deposit composition.

In other embodiments, the material of the functionalized material comprises one or more of an organic material, a metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene.

In certain embodiments, the material comprises one or more doping substances. In other embodiments, the one or more doping substances comprises Zr, Sb, Li, Mg, Y, Nb, Cu, or Mo.

In some embodiments, the material of the functionalized material comprises one or more of an organic material, a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene. In yet other embodiments, the material of the functionalized material comprises one or more of an a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene. In still other embodiments, the material of the functionalized material comprises one or more of TiO₂, SnO₂, NiOₓ, CuO, ZnO, Zn₂SO₄, WO₃, In₂O₃, SrTiO₃, Nb₂O₅, BaSnO₃, Y:SnO₂, or Cu:NiOₓ.

In certain embodiments, the material of the functionalized material comprises one or more of SnO₂, NiOₓ, Y:SnO₂, or Cu:NiOₓ.

In some embodiments, the one or more functionalizing compounds is one or more of:

(1) R₁ₐ—CO—OH (I),
or salts thereof, where R₁ₐ is substituted or unsubstituted alkyl;

(2) R₂ₐ—O—CS₂⁻M⁺₂ₐ (II),
where R₂ₐ is substituted or unsubstituted alkyl, and M⁺₂ₐ is a cation;

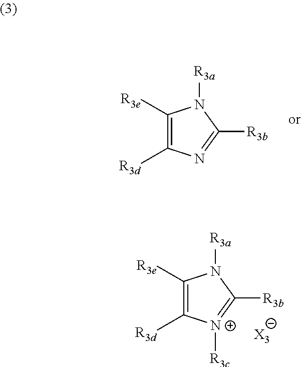

where X₃ is an anion; R₃ₐ, R_{3c}, R_{3d}, and R₃ₑ is the same or different and is H, substituted or unsubstituted alkyl, or substituted or unsubstituted aryl; R_{3b} is H, substituted or unsubstituted alkyl, substituted or unsubstituted aryl, substituted or unsubstituted Lewis base, quaternary nitrogen salts, carboxylates, xanthates, alkoxides, or thiolates;

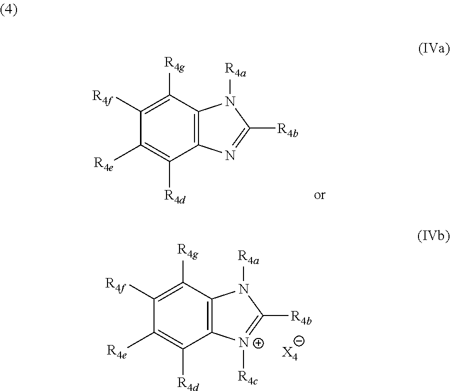

where X₄ is an anion; R₄ₐ, R_{4c}, R_{4d}, R₄ₑ, R_{4f}, and R_{4g} is the same or different and is H, substituted or unsubstituted alkyl, or substituted or unsubstituted aryl; R_{4b} is H, substituted or unsubstituted alkyl, substituted or unsubstituted aryl, substituted or unsubstituted Lewis base, quaternary nitrogen salts, carboxylates, xanthates, alkoxides, or thiolates;

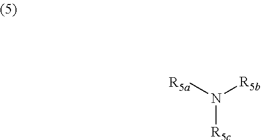

where R₅ₐ, R_{5b}, and R_{5c} is the same or different and is H, substituted or unsubstituted alkyl, or substituted or unsubstituted aryl;

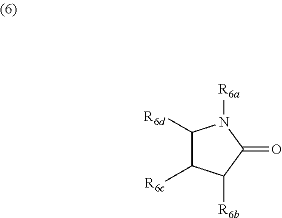

where R_{6b}, R_{6c}, and R₆ₐ is the same or different and is H, substituted or unsubstituted alkyl, or substituted or unsubstituted aryl; R₆ₐ is H, substituted or unsubstituted alkyl, substituted or unsubstituted aryl, where the R₆ₐ substituted alkyl is optionally substituted with one or more substituted or unsubstituted Lewis bases, quaternary nitrogen salts, carboxylates, xanthates, alkoxides, or thiolates, where the R₆ₐ substituted aryl is optionally substituted with one or more substituted or unsubstituted Lewis bases, quaternary nitrogen salts, carboxylates, xanthates, alkoxides, or thiolates; or

(7) R₇ₐ—NH—CS₂⁻M⁺₇ₐ (VII),
where R₇ₐ is a substituted or unsubstituted alkyl and M⁺₂ₐ is a cation.

In certain embodiments, R₁ₐ is a substituted or unsubstituted C₁-C₈ alkyl, methyl, ethyl, propyl, or butyl. In other embodiments, R₂ₐ is a substituted or unsubstituted alkyl C₁-C₃₆ alkyl, methyl, ethyl, propyl, butyl, dodecyl, or octadecyl; M⁺₂ₐ is Na⁺, K⁺, or Li⁺; or a combination thereof. In yet other embodiments, X₃ is Cl—, Br⁻, I⁻, BF₄⁻, PF₆⁻, or CF₃SO₃⁻; R₃ₐ, R_{3c}, R_{3d}, and R₃ₑ is the same or different and is H, substituted or unsubstituted C₁-C₈ alkyl, or substituted or unsubstituted phenyl; R_{3b} is H, substituted or unsubstituted C₁-C₈ alkyl, substituted or unsubstituted phenyl, —C(O)H, —C(O)OH, —C(O)NHR_{3f}, —CH₂OR_{3f}, —CH₂NHR_{3f}, quaternary nitrogen salts, carboxylates, xanthates, alkoxides, or thiolates, R_{3f} is H, substituted or unsubstituted C₁-C₈ alkyl; or a combination thereof. In still other embodiments, X₄ is Cl⁻, Br⁻, I⁻, BF₄⁻, PF₆⁻, or CF₃SO₃⁻; R₄ₐ, R_{4c}, R_{4d}, R₄ₑ, R_{4f}, and R_{4g} is the same or different and is H, substituted or unsubstituted C₁-C₈alkyl, or substituted or unsubstituted phenyl; R_{4b} is H, substituted or unsubstituted C₁-C₈ alkyl, substituted or unsubstituted phenyl, —C(O)H, —C(O)OH, —C(O)NHR₄ₕ, —CH₂OR₄ₕ, —CH₂NHR₄ₕ, quaternary nitrogen salts, carboxylates, xanthates, alkoxides, or thiolates, R₄ₕ is H, substituted or unsubstituted C₁-C₈ alkyl; or a combination thereof. In certain embodiments, R₅ₐ, R_{5b}, and R_{5c} is the same or different and is H, substituted or unsubstituted C₁-C₈ alkyl, or substituted or unsubstituted phenyl. In other embodiments, R_{6b}, R_{6c}, and R_{6d} is the same or different and is H, substituted or unsubstituted C₁-C₈ alkyl, or substituted or unsubstituted phenyl; R₆ₐ is H, substituted or unsubstituted C₁-C₈ alkyl, substituted or unsubstituted phenyl, where the R₆ₐ substituted alkyl is optionally substituted with one or more —C(O)H, —C(O)OH, —C(O)NHR₆ₑ, —CH₂OR₆ₑ, —CH₂NHR₆ₑ, quaternary nitrogen salts, carboxylates, xanthates, alkoxides, or thiolates, where the R₆ₐ substituted aryl is optionally substituted with one or more —C(O)H, —C(O)OH, —C(O)NHR₆ₑ, —CH₂OR₆ₑ, —CH₂NHR₆ₑ, quaternary nitrogen salts, carboxylates, xanthates, alkoxides, or thiolates, R₆ₑ is H, substituted or unsubstituted C₁-C₈ alkyl; or a combination thereof. In other embodiments, R₇ₐ is a substituted or unsubstituted alkyl C₁-C₃₆ alkyl, methyl, ethyl, propyl, butyl, dodecyl, or octadecyl; M⁺₇ₐ is Na⁺, K⁺, or Li⁺; or a combination thereof.

In some embodiments, formula (IIIb) is

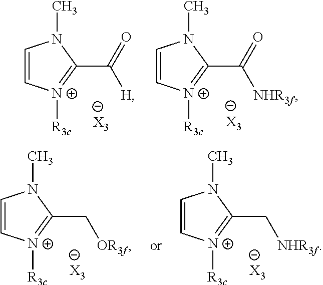

In certain embodiments, formula (V) is selected from triarylamines (TAA), substituted TAA, triphenylamine, substituted triphenylamines, triethylamine and substituted triethylamines.

In other embodiments, the functionalized material comprises one or more of a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene, where each is independently functionalized with (i) one or more of formula (I) or salts thereof, where R₁ₐ is C₁-C₄ alkyl, (ii) one or more of formula (II), where R₂ₐ is C₁-C₂₇ alkyl and M⁺₂ₐ is Na⁺, K⁺, or Li⁺, (iii) triethylamine, or (iv) a combination thereof. In still other embodiments, the functionalized material comprises one or more of a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene, where each is independently functionalized with one or more of formula (I) or salts thereof, where R₁ₐ is C₁-C₄ alky. In yet other embodiments, the functionalized material comprises one or more of TiO₂, ZnO, Y:SnO₂, Cu:NiOₓ, NiOₓ, or SnO₂ where each is independently functionalized with acetate, propionate, triethylamine, Na C₁₈ alkyl xanthate, Na C₁₂ alkyl xanthate, or a combination thereof. In certain embodiments, the functionalized material comprises one or more of TiO₂, ZnO, NiOₓ, or SnO₂ where each is independently functionalized with one or both of acetate or propionate.

In some embodiments, the solvent comprises a protic solvent, an anhydrous protic solvent, anhydrous methanol, anhydrous ethanol, anhydrous isopropanol, anhydrous C₁₋₁₀ alcohol, THF, dimethyl ether, diethyl ether, an anhydrous ether, an ether, chlorobenzene (CB), or a combination thereof.

In certain embodiments, the depositing step is performed by one or more of blade coating, spin coating, slot die, gravure, flexo, spray, or inkjet. In still other embodiments, the depositing step is performed by blade coating.

In some embodiments, the heating step comprises annealing or intense pulsed light (IPL). In other embodiments, the heating step comprises heating at about 80 °C to about 120 °C for about 5 to about 20 minutes. In still other embodiments, the heating step removes some or all of the one or more functionalizing compounds.

In some embodiments, the removing step occurs. In other embodiments, the removing step occurs by heat or by intense pulsed light (IPL).

In other embodiments, (i) the heating step removes some of the one or more functionalizing compounds and (ii) the removing step occurs, and further removes some of or all of the remainder of the one or more functionalizing compounds.

In some embodiments, the perovskite layer comprises one or more of CH₃NH₃PbX₃, CH₃NH₃PbI₃, H₂NCHNH₂PbX₃, CH₃NH₃SnX₃, or Csₐ(CH₅NH₃)_{b}(CH₃NH₃)_{c}PbI_{3(1-y)}Br_{3y} where X is a halogen which can be the same or different between or within each formula, a is about 0 to about 0.5, b is about 0 to about 0.8, c is about 0 to about 0.8, and y is about 0 to about 1.

In certain embodiments, the PSC is a p-i-n type device. In other embodiments, the PSC is an n-i-p type device.

In some embodiments, the perovskite layer is part of a structure that further comprises one or more of an anode; a hole transport layer (HTL); or a cathode. In other embodiments, the perovskite layer is part of a structure that further comprises one or more of an anode; an electron transport layer (ETL); or a cathode.

In certain embodiments, the method further comprises adding a cathode. In other embodiments, the method further comprises adding a cathode and the method for adding the cathode is screen printing, thermal evaporation, sputtering, or atomic layer deposition. In yet other embodiments, the method further comprises adding a cathode and the method for adding the cathode is thermal evaporation. In some embodiments, the method further comprises adding a cathode and the cathode is Fe, C, Ni, Pt, Ag, Al, or Cu. In certain embodiments, the method further comprises adding a cathode and the cathode is Ag, Al, or Cu.

In some embodiments, the PSC has an open circuit voltage (V_{OC}) of from about 0.7 V to about 1.3V. In certain embodiments, the PSC has fill factor (FF) of from about 35% to about 80%. In other embodiments, the PSC has a current density (J_{sc}) of from about 10 mA/cm² to about 25 mA/cm². In still other embodiments, the PSC has a Power Conversion Efficiency (PCE) of from about 4% to about 20%.

In some embodiments, the PSC is a flexible PSC.

Some embodiments of the invention include a PSC made according to any method disclosed herein. In certain embodiments, the PSC comprises an anode; a hole transport layer (HTL); an electron transport layer (ETL) and a perovskite layer, prepared according to any method disclosed herein (e.g., original claim 1); and a cathode. In certain embodiments, the anode is ITO/glass or FTL/glass. In other embodiments, the HTL is NiOₓ, PTAA or PTAA/PFN. In some embodiments, the perovskite layer is one or more of CH₃NH₃PbX₃, CH₃NH₃PbI₃, H₂NCHNH₂PbX₃, or CH₃NH₃SnX₃, where X is a halogen which can be the same or different between or within each formula. In yet other embodiments, the cathode is Fe, C, Ni, Pt, Ag, Al, or Cu. In still other embodiments, the cathode is Ag, Al, or Cu.

Some embodiments of the invention include a PSC made according to any method disclosed herein. In certain embodiments, the PSC comprises an anode; an ETL; an HTL and a perovskite layer, prepared according to any method disclosed herein (e.g., original claim 1); and a cathode. In some embodiments, the anode is ITO/glass or FTL/glass. In other embodiments, the ETL is SnO₂, TiO₂, or ZnO. In yet other embodiments, the perovskite layer is one or more of CH₃NH₃PbX₃, CH₃NH₃PbI₃, H₂NCHNH₂PbX₃, or CH₃NH₃SnX₃, where X is a halogen which can be the same or different between or within each formula. In certain embodiments, the cathode is Fe, C, Ni, Pt, Ag, Al, or Cu. In still other embodiments, the cathode is Ag, Al, or Cu.

Other embodiments of the invention are also discussed herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The following drawings form part of the present specification and are included to further demonstrate certain aspects of the present invention. The invention may be better understood by reference to one or more of these drawings in combination with the description of specific embodiments presented herein.

FIG. 1: Schematic illustration of the synthesis of hydrous-SnO₂ (a), functionalization of hydrous-SnO₂ with acetic acid to yield SnO₂-A (b), and preparation of a stable colloidal dispersion in anhydrous ethanol (c), XRD diffraction patterns (d), and FTIR spectra of hydrous-SnO₂ and SnO₂-A (e).

FIG. 2: XRD patterns (a), photoluminescence spectra (b), and time-resolved photoluminescence data for CH₃NH₃PbI₃ perovskite films before and after deposition of SnO₂-A (c).

FIG. 3: Schematic illustration of the blade coating of SnO₂-A on the perovskite (a) and cross-sectional SEM image of the full device (b).

FIG. 4: The device structure of p-i-n PSC having a SnO₂-A over perovskite film (a), J-V curve of the champion device (b), and corresponding photovoltaic parameters (c).

FIG. 5: Stability study J-V characteristics of unencapsulated p-i-n devices before (1) and after (2) storage for 40 days in a nitrogen flow box.

FIG. 6: Preparation of NiOₓ inks.

FIG. 7: SEM images of NiOₓ particles. (a) As prepared NiOₓ powder showing particle agglomeration. (b) NiOₓ films prepared using the 0X ink showing uniform dispersion of small particles. Scale bars are 1 μm.

FIG. 8: (a) UV-Vis of the 12X ligand, 12X ink and 0X ink in the same solvent system in a 1 mm quartz cell showing coordination of 12X to NiOₓ in the ink. (b) FT-IR of the 12X ligand as a powder and the 12X ink as a film showing coordination of 12X to NiOₓ in the ink.

FIG. 9: (a) TGA of 12X ligand as a solid and the 12X ink as a thick film confirming degradation of the xanthate at temperatures above 300 °C (b-d) SEM images of 0X, 12X, and 18X films prepared by blade coating showing changes in film uniformity in the presence of xanthate ligands. Scale bars are 5 μm.

FIG. 10: (a-d) Statistical comparison of photovoltaic parameters for 0.25 cm² cells prepared with 0X-18X inks. (e) Schematic illustration of p-i-n device stack with expected energy alignment in eV.

FIG. 11: J-V curves for 1 cm² devices prepared with 0X and 18X inks.

FIG. 12: (a) Schematic illustration of n-i-p device. (b) Optical image of the 0X coated perovskite. (c) Optical images of perovskite film prior to NiOₓ coating. (d) PXRD of perovskite film as prepared (red) and after deposition of 0X ink (grey) showing the formation of a new peak at 9.5°.

FIG. 13: PXRD of Cu doped and undoped NiOₓ nanoparticles. Extra peak at 29 is sodium nitrate and has been successfully removed by further washing.

FIG. 14: Change in particles mean size with undisturbed aging over the course of a week.

FIG. 15: JV curves of the highest preforming NiOₓ and Cu doped films. Values summarized in Table C₁.

FIG. 16: (a) Energy Dispersive X-ray Spectrometry (EDS) spectra of Y:SnO₂. (b) XRD patterns of pristine SnO₂ and Y:SnO₂. Elemental mapping of (c) tin, (d) oxygen, and (e) yttrium present in Y:SnO₂ nanoparticles.

FIG. 17: XPS spectrum of SnO₂ and Y:SnO₂ films (a) XPS survey spectrum, (b) high-resolution XPS spectra of Sn 3d (the curves represent the unfitted Sn 3d curves (solid line), curves after fitting (medium dashed line), the fitted curve for Sn 3d_{5/2} (long dashed line), and the fitted curve of Sn 3d_{3/2} (short dashed line)), and (c) XPS spectra Y 3d.

FIG. 18: (a) Functionalization of Y:SnO₂ and dilution of functionalized Y:SnO₂ in anhydrous ethanol, (b) Schematic of the blade coating, (c) SEM image of the perovskite film before Y:SnO₂ deposition, and (d) SEM image of the perovskite film after Y:SnO₂ deposition.

FIG. 19: (a) XRD diffraction patterns and (b) UV-Vis spectra of perovskite films before and after the deposition of SnO₂-A.

FIG. 20: Steady-state PL spectra of the PET/perovskite, PET/perovskite/SnO₂-A and PET/perovskite/Y:SnO₂-A samples.

FIG. 21: Device performance statistics vs Yttrium doping concentration. The photovoltaic parameters (a) V_{OC}, (b) J_{SC}, (c) FF, and (d) PCE.

FIG. 22: (a) Digital image of f-PSCs, (b) J-V curve of the champion 0.1 cm² device, and (c) J-V hysteresis of Y:SnO₂-A device.

FIG. 23: Illustrative scheme for preparing Y doped SnO₂.

FIG. 24: Analysis of J-V characteristics of Y doped SnO₂-Average Current Density (J_{sc}) and Fill Factor (FF) percent.

FIG. 25: Analysis of J-V characteristics of Y doped SnO₂-Potential (V_{OC}) and Power Conversion Efficiency (PCE) percent.

FIG. 26: (a) PXRD of MAPI as deposited and with a NiOₓ top film. (b) Photoluminescence spectra of MAPI, MAPI/NiOₓ, and MAPI/NiOₓ/PA.

### DETAILED DESCRIPTION

While embodiments encompassing the general inventive concepts may take diverse forms, various embodiments will be described herein, with the understanding that the present disclosure is to be considered merely exemplary, and the general inventive concepts are not intended to be limited to the disclosed embodiments.

Some embodiments of the invention include inventive methods for preparing perovskite solar cells (PSCs). In certain embodiments, the method comprises dissolving a functionalized material (e.g., a material that is functionalized with one or more functionalizing compounds) in a solvent, depositing a deposit composition on a perovskite layer where the deposit composition comprises the dissolved functionalized material, heating the deposit composition, and optionally removing some or all of the one or more functionalizing compounds from the deposit composition. Additional embodiments of the invention are also disclosed herein. As used herein (unless otherwise specified), the term “alkyl” means a monovalent, straight or branched hydrocarbon chain. For example, the terms “C₁-C₇ alkyl” or “C₁-C₄ alkyl” refer to straight- or branched-chain saturated hydrocarbon groups having from 1 to 7 (e.g., 1, 2, 3, 4, 5, 6, or 7), or 1 to 4 (e.g., 1, 2, 3, or 4), carbon atoms, respectively. Examples of C₁-C₇ alkyl groups include, but are not limited to, methyl, ethyl, n-propyl, i-propyl, n-butyl, s-butyl, t-butyl, n-pentyl, s-pentyl, n-hexyl, and n-septyl. Examples of C₁-C₄ alkyl groups include, but are not limited to, methyl, ethyl, n-propyl, i-propyl, n-butyl, s-butyl, and t-butyl.

As used herein (unless otherwise specified), the term “alkoxy” means any of the above alkyl groups which is attached to the remainder of the molecule by an oxygen atom (alkyl-O—). Examples of alkoxy groups include, but are not limited to, methoxy (sometimes shown as MeO—), ethoxy, isopropoxy, propoxy, and butyloxy.

As used herein (unless otherwise specified), the term “aryl” means a monovalent, monocyclic or bicyclic, 5, 6, 7, 8, 9, 10, 11, or 12 membered aromatic hydrocarbon group, when unsubstituted. Examples of aryl groups include, but are not limited to, phenyl, naphthyl, tolyl, and xylyl. For a bicyclic aryl that is designated as substituted, one or both rings can be substituted.

As used herein (unless otherwise specified), the term “halogen” means monovalent Cl, F, Br, or I.

As used herein (unless otherwise specified), the term “hetero atom” means an atom selected from nitrogen atom, oxygen atom, or sulfur atom.

As used herein (unless otherwise specified), the terms “hydroxy” or “hydroxyl” indicates the presence of a monovalent-OH group.

As used herein (unless otherwise specified), the term “Lewis base” means any chemical species that has a filled orbital containing an electron pair which is not involved in bonding but may form a dative bond (i.e., a two-center, two-electron covalent bond in which the two electrons derive from the same atom) with another chemical (e.g., a chemical that has an empty orbital capable of accepting an electron pair). Some Lewis bases can be conventional amines (e.g., ammonia and alkyl amines) or pyridine and its derivatives. Some classes of Lewis bases are (a) amines (e.g., NR₃ where R is independently H, alkyl, or aryl) (b) phosphines (e.g., PR₃ where R is independently alkyl or aryl), or (c) compounds of O, S, Se and Te in oxidation state −2, (e.g., water, ethers, or ketones). Other examples of Lewis bases include (a) simple anions, such as H⁻ and F⁻, (b) lone-pair-containing species, such as H₂O, NH₃, HO⁻, and CH₃⁻, (c) complex anions, such as sulfate, and (d) electron-rich T-systems, such as ethyne, ethene, and benzene. Other examples of Lewis bases include Et₃N, quinuclidine, pyridine, acetonitrile, Et₂O, THF, acetone, EtOAc, DMA, DMSO, tetrahydrothiophene, and trimethylphosphine. Lewis bases can be monovalent moieties. Lewis bases can be substituted or unsubstituted.

As used herein (unless otherwise specified), the term “substituted” (e.g., as in substituted alkyl) means that one or more hydrogen atoms of a chemical group (with one or more hydrogen atoms) can be replaced by one or more non-hydrogen substituents selected from the specified options. The replacement can occur at one or more positions. The term “optionally substituted” means that one or more hydrogen atoms of a chemical group (with one or more hydrogen atoms) can be, but is not required to be substituted. Non-hydrogen substituents include but are not limited to halogen (e.g., F, Cl, Br, or I), hydroxy (—OH), methanoyl (—COH), —COCH₃, carboxy (—CO₂H), ethynyl (—CCH), cyano (—CN), sulfo (—SO₃H), methyl, ethyl, perfluorinated methyl, perfluorinated ethyl, amines, alcohols, ethers, thiols, thioethers, amides, Lewis bases, quaternary nitrogen salts, carboxylates, xanthates, alkoxides, thiolates, aldehydes, —C(O)OH, —C(O)NHR, —CH₂OR, or —CH₂NHR, where R can be H, unsubstituted alkyl (e.g., C₁, C₂, C₃, C₄, C₅, C₆, C₇, or C₈ alkyl) or alkyl (e.g., C₁, C₂, C₃, C₄, C₅, C₆, C₇, or C₈ alkyl) substituted (e.g., with one or more of halogen (e.g., F, Cl, Br, or I), hydroxy (—OH), methanoyl (—COH), —COCH₃, carboxy (—CO₂H), ethynyl (—CCH), cyano (—CN), sulfo (—SO₃H), methyl, ethyl, perfluorinated methyl, perfluorinated ethyl, amines, alcohols, ethers, thiols, thioethers, amides, or aldehydes).

### Methods for Preparing Perovskite Solar Cells (PSCs)

Some embodiments of the invention include methods for preparing a Perovskite Solar Cell (PSC), as disclosed herein. In certain embodiments, the method comprises (a) dissolving a functionalized material in a solvent, where the functionalized material is a material that is functionalized with one or more functionalizing compounds, (b) depositing (e.g., layering) a deposit composition (e.g., an ink) on a perovskite layer where the deposit composition comprises the dissolved functionalized material; (c) heating the deposit composition on the perovskite layer; and (d) optionally removing some or all of the one or more functionalizing compounds.

In some embodiments, the material of the functionalized material can be any suitable material. In certain embodiments, the material of the functionalized material can be one or more of an organic material, a metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene. NiOₓ refers to NiO (Ni²⁺), Ni₂O₃ (Ni³⁺) and/or mixtures of NiO and Ni₂O₃. In some embodiments, the material of the functionalized material can be one or more of an organic material, a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene. In other embodiments, the material can be doped using one or more of any suitable doping substances (e.g., Zr, Sb, Li, Mg, Y, Nb, Cu, or Mo). A material that is doped can be but is not limited to Cu:NiOₓ or Y:SnO₂. In some embodiments, the material can be SnO₂, NiOₓ, Cu:NiOₓ or Y:SnO₂. In some embodiments, the material (e.g., the material that is doped) can be functionalized (e.g., the material is bonded to one or more of a functionalizing compound using covalent and/or ionic bonds) with one or more functionalizing compounds (e.g., one or more suitable functionalizing compounds). In other embodiments, the material (e.g., the material that is doped) can be functionalized (e.g., the material is bonded to the one or more functionalizing compounds using covalent bonds, ionic bonds, or both) with one or more of the following the functionalizing compounds (e.g., one or more selected from Formulas (I), (II), (IIIa), (IIIb), (IVa), (IVb), (V), (VI), or (VI)):

(1) R₁ₐ—CO—OH (I),
or salts thereof (e.g., where the cation can be, for example, Na⁺, K⁺, Li⁺, Mg²⁺, Ca²⁺, or any suitable cation), where R₁ₐ can be substituted or unsubstituted alkyl (e.g., C₁, C₂, C₃, C₄, C₅, C₆, C₇, or C₈ alkyl, or methyl, ethyl, propyl, or butyl);

(2) R₂ₐ—O—CS₂⁻M⁺₂ₐ (II),

where R₂ₐ can be substituted or unsubstituted alkyl (e.g., C₁-C₁₈ alkyl, C₁-C₂₇ alkyl, C₁-C₃₆ alkyl, or C₁, C₂, C₃, C₄, C₅, C₆, C₇, C₈, C₉, C₁₀, C₁₁, C₁₂, C₁₃, C₁₄, C₁₅, C₁₆, C₁₇, C₁₈, C₁₉, C₂₀, C₂₁, C₂₂, C₂₃, C₂₄, C₂₅, C₂₆, C₂₇, C₂₈, C₂₉, C₃₀, C₃₁, C₃₂, C₃₃, C₃₄, C₃₅, or C₃₆ alkyl or, methyl, ethyl, propyl, butyl, dodecyl, or octadecyl), and M⁺₂ₐ can be any suitable cation (e.g., Na⁺, K⁺, or Li⁺);

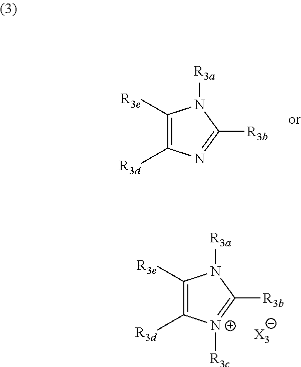

(e.g., imidazoles and imidazolium salts thereof) where X₃ can be Cl⁻, Br⁻, I⁻, BF₄⁻, PF₆⁻, CF₃SO₃⁻, or any suitable anion. R₃ₐ, R_{3c}, R_{3d}, and R₃ₑ can be the same or different and can be H, substituted or unsubstituted alkyl (e.g., C₁, C₂, C₃, C₄, C₅, C₆, C₇, or C₈ alkyl), or substituted or unsubstituted aryl (e.g., phenyl). R_{3b} can be H, substituted or unsubstituted alkyl (e.g., C₁, C₂, C₃, C₄, C₅, C₆, C₇, or C₈ alkyl), substituted or unsubstituted aryl (e.g., phenyl), substituted or unsubstituted Lewis base (e.g. with amines, alcohols, ethers, thiols, thioethers, amides, or aldehydes, such as —C(O)H, C(O)OH, —C(O)NHR_{3f}, —CH₂OR_{3f}, or —CH₂NHR_{3f}) or charged functional groups (e.g. quaternary nitrogen salts, carboxylates, xanthates, alkoxides, or thiolates). R_{3f} can be H, substituted or unsubstituted alkyl (e.g., C₁, C₂, C₃, C₄, C₅, C₆, C₇, or C₈ alkyl). Some examples of formula (IIIb) include, but are not limited to

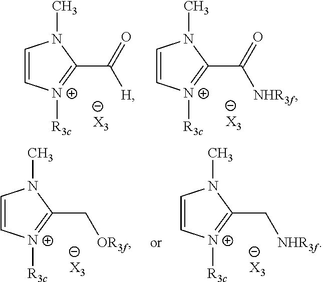

where R_{3c} is H or unsubstituted alkyl (e.g., C₁, C₂, C₃, C₄, C₅, C₆, C₇, or C₈ alkyl), R_{3f} is H or unsubstituted alkyl (e.g., C₁, C₂, C₃, C₄, C₅, C₆, C₇, or C₈ alkyl), and X₃ is Cl⁻, Br⁻, I⁻, BF₄⁻, PF₆⁻, or CF₃SO₃⁻;

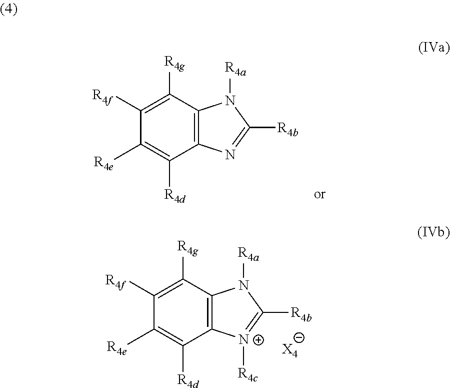

(e.g., benzimidazoles and benzimidazolium salts thereof). X₄ can be Cl⁻, Br⁻, I⁻, BF₄⁻, PF₆⁻, CF₃SO₃⁻, or any suitable anion. R₄ₐ, R_{4c}, R_{4d}, R₄ₑ, R_{4f}, and R_{4g} can be the same or different and can be H, substituted or unsubstituted alkyl (e.g., C₁, C₂, C₃, C₄, C₅, C₆, C₇, or C₈ alkyl), or substituted or unsubstituted aryl (e.g., phenyl). R_{4b} can be H, substituted or unsubstituted alkyl (e.g., C₁, C₂, C₃, C₄, C₅, C₆, C₇, or C₈ alkyl), substituted or unsubstituted aryl (e.g., phenyl), substituted Lewis bases (e.g. with amines, alcohols, ethers, thiols, thioethers, amides, or aldehydes, such as —C(O)H, —C(O)OH, —C(O)NHR₄ₕ, —CH₂OR₄ₕ, or —CH₂NHR₄ₕ) or charged functional groups (e.g. quaternary nitrogen salts, carboxylates, xanthates, alkoxides, or thiolates). R₄ₕ can be H, substituted or unsubstituted alkyl (e.g., C₁, C₂, C₃, C₄, C₅, C₆, C₇, or C₈ alkyl);

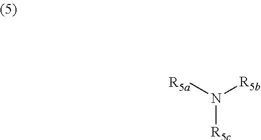

R₅ₐ, R_{5b}, and R_{5c} can be the same or different and can be H, substituted or unsubstituted alkyl (e.g., C₁, C₂, C₃, C₄, C₅, C₆, C₇, or C₈ alkyl), or substituted or unsubstituted aryl (e.g., phenyl). Examples of formula (V) include triarylamines (TAA), substituted TAA, triphenylamine, substituted triphenylamines, triethylamine and substituted triethylamines;

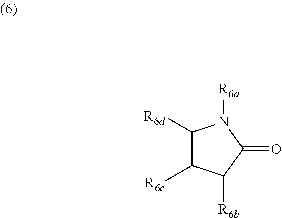

(such as 2-pyrrolidinones) R_{6b}, R_{6c}, and R_{6d} can be the same or different and can be H, substituted or unsubstituted alkyl (e.g., C₁, C₂, C₃, C₄, C₅, C₆, C₇, or C₈ alkyl), or substituted or unsubstituted aryl (e.g., phenyl). R₆ₐ can be H, substituted or unsubstituted alkyl (e.g., C₁, C₂, C₃, C₄, C₅, C₆, C₇, or C₈ alkyl), substituted or unsubstituted aryl (e.g., phenyl). R₆ₐ substituted alkyl can be optionally substituted with one or more with Lewis bases (e.g. with amines, alcohols, ethers, thiols, thioethers, amides, or aldehydes, such as —C(O)H, —C(O)OH, —C(O)NHR₆ₑ, —CH₂OR₆ₑ, or —CH₂NHR₆ₑ) or charged functional groups (e.g. quaternary nitrogen salts, carboxylates, xanthates, alkoxides, or thiolates). R₆ₐ substituted aryl can be optionally substituted with one or more with Lewis bases (e.g. with amines, alcohols, ethers, thiols, thioethers, amides, or aldehydes, such as —C(O)H, —C(O)OH, —C(O)NHR₆ₑ, —CH₂OR₆ₑ, or —CH₂NHR₆ₑ) or charged functional groups (e.g. quaternary nitrogen salts, carboxylates, xanthates, alkoxides, or thiolates). R₆ₑ can be H, substituted or unsubstituted alkyl (e.g., C₁, C₂, C₃, C₄, C₅, C₆, C₇, or C₈ alkyl); or

(7) R₇ₐ—NH—CS₂⁻M⁺₇ₐ (VII),
where R₇ₐ can be substituted or unsubstituted alkyl (e.g., C₁-C₁₈ alkyl, C₁-C₂₇ alkyl, C₁-C₃₆ alkyl, or C₁, C₂, C₃, C₄, C₅, C₆, C₇, C₈, C₉, C₁₀, C₁₁, C₁₂, C₁₃, C₁₄, C₁₅, C₁₆, C₁₇, C₁₈, C₁₉, C₂₀, C₂₁, C₂₂, C₂₃, C₂₄, C₂₅, C₂₆, C₂₇, C₂₈, C₂₉, C₃₀, C₃₁, C₃₂, C₃₃, C₃₄, C₃₅, or C₃₆ alkyl or, methyl, ethyl, propyl, butyl, dodecyl, or octadecyl), and M⁺₇ₐ can be any suitable cation (e.g., Na⁺, K⁺, or Li⁺).

In certain embodiments, the functionalized material comprises one or more of an organic material, a metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene, where each can be independently functionalized with one or more of R—CO—OH, where R can be C₁-C₄ alky or salts thereof. In still other embodiments, the functionalized material comprises one or more of a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene, where each is independently functionalized with (i) one or more of formula (I) or salts thereof, where R₁ₐ is C₁-C₄ alkyl, (ii) one or more of formula (II), where R₂ₐ is C₁-C₂₇ alkyl and M⁺₂ₐ is Na⁺, K⁺, or Li⁺, (iii) triethylamine, or (iv) a combination thereof. In yet other embodiments, the functionalized material comprises one or more of a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene, where each is independently functionalized with one or more of formula (I) or salts thereof, where R₁ₐ is C₁-C₄ alky. In certain embodiments, the functionalized material comprises one or more of TiO₂, ZnO, Y:SnO₂, Cu:NiOₓ, NiOₓ, or SnO₂ where each is independently functionalized with acetate, propionate, triethylamine, Na C₁₈ alkyl xanthate, Na C₁₂ alkyl xanthate, Na C₄ xanthate, Na xanthate, or a combination thereof. In certain embodiments, the functionalized material comprises one or more of TiO₂, ZnO, Y:SnO₂, Cu:NiOₓ, NiOₓ, or SnO₂ where each is independently functionalized with acetate, propionate, triethylamine, Na C₁₈ alkyl xanthate, Na C₁₂ alkyl xanthate, or a combination thereof. In other embodiments, the functionalized material comprises one or more of TiO₂, ZnO, NiOₓ, or SnO₂ where each is independently functionalized with one or both of acetate or propionate. In some embodiments, the functionalized material does not comprise NiOₓ functionalized with C₁₈ acetate.

In other embodiments, the solvent comprises any suitable solvent, such as but not limited to any suitable protic solvent, any suitable anhydrous protic solvent, anhydrous methanol, anhydrous ethanol, anhydrous isopropanol, anhydrous C₁, C₂, C₃, C₄, C₅, C₆, C₇, C₈, C₉, or C₁₀ alcohol, THF, dimethyl ether, diethyl ether, any suitable anhydrous ether, any suitable ether, chlorobenzene (CB), or combinations thereof. In some embodiments, the solvent comprises anhydrous ethanol, anhydrous isopropanol, chlorobenzene (CB), or combinations thereof. In other embodiments, the solvent does not degrade (e.g., does not significantly and/or detrimentally degrade) the perovskite layer. In some embodiments, the solvent does not comprise CB. In some embodiments, the solvent does not comprise isopropanol.

In certain embodiments, the deposit composition comprises the dissolved functionalized material, where the dissolved (e.g., completely dissolved or partially dissolved) functionalized material comprises functionalized material and solvent. In some embodiments, the functionalized material can be completely dissolved in the solvent. In still other embodiments, the functionalized material can be partially dissolved (e.g., at least 80%, at least 90%, or at least 99% dissolved by weight of total functionalized material, or 99.9%, 99%, 98%, 95%, 90%, 85%, or 80% dissolved by weight of total functionalized material) in the solvent. In certain embodiments, the concentration of the functionalized material in the deposit composition can be any suitable concentration (e.g., from 0.01 to 90.0, from 0.01 to 50.0, from 0.01 to 10.0, from 0.1 to 5.0, from 0.5 to 3.0% (m/v), or 0.01, 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.5, 4.0, 5.0, 6.0, 7.0, 8.0, 9.0, 10.0, 20.0, 30.0, 40.0, 50.0, 60.0, 70.0, 80.0, or 90.0% (m/v) (or g/100 mL)). In other embodiments, the concentration of the functionalized material in the deposit composition can be any suitable concentration (e.g., from 0.01 to 99.9, from 0.01 to 50.0, from 0.01 to 10.0, from 0.1 to 5.0, from 0.5 to 3.0 wt/wt %, or 0.01, 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.5, 4.0, 5.0, 6.0, 7.0, 8.0, 9.0, 10.0, 20.0, 30.0, 40.0, 50.0, 60.0, 70.0, 80.0, 90.0, 95.0, 99.0, or 99.9 wt/wt %, based on the total weight of the deposit composition). In yet other embodiments, the deposit composition (e.g., an ink) further comprises one or more of any suitable doping substances (e.g., Zr, Sb, Li, Mg, Y, Nb, Cu or Mo). As described herein, the deposit composition can comprise a functionalized material; the functionalized material can be a material that is functionalized with one or more functionalizing compounds. In other embodiments, the material encompasses material that is doped using one or more of any suitable doping substances (e.g., Zr, Sb, Li, Mg, Y, Nb, Cu or Mo). A material that is doped can be but is not limited to Cu:NiOₓ or Y:SnO₂. In some embodiments, the material (e.g., the doped material) can be functionalized (e.g., the material is bonded to the one or more functionalizing compounds using covalent and/or ionic bonds) with one or more suitable functionalizing compounds. In some embodiments, the deposit composition does not comprise NiOₓ functionalized with C₁₈ acetate dissolved in CB.

In other embodiments, the depositing can be performed by one or more of any suitable depositing method. In yet other embodiments, the depositing can be performed by one or more of blade coating, spin coating, pulsed laser deposition, electron beam evaporation, spray pyrolysis, co-sputtering, atomic layer deposition, slot die, gravure, flexo, spray, or inkjet. In other embodiments, the depositing can be performed by one or more of blade coating, spin coating, slot die, gravure, flexo, spray, or inkjet. In still other embodiments, the depositing can be performed by blade coating. In certain embodiments, the deposit composition is layered on the perovskite layer. In some embodiments, the deposit composition is layered on the perovskite layer so that the perovskite layer is at least partially covered by the deposit composition or is completely covered by the deposit composition. In other embodiments, the solvent during depositing does not degrade (e.g., does not significantly and/or detrimentally degrade) the perovskite layer. In certain embodiments, the depositing does not use vacuum technology such as, but not limited to, atomic layer deposition, sputtering, or evaporation.

In some embodiments, the heating can be accomplished using any suitable heating method, such as but not limited to, hot plates, ovens (e.g., convective ovens), or intense pulsed light (IPL) (examples of IPL details and methods are disclosed in U.S. Pat. No. 10,950,794 issued Mar. 16, 2021, which is herein incorporated by reference in its entirety). In still other embodiments, the heating comprises annealing (e.g., by IPL). In still other embodiments, the heating comprises heating by intense pulsed light (IPL). In yet other embodiments, the heating comprises heating (e.g., using hot plates, ovens (e.g., convective ovens), or IPL) at about 80 °C to about 120 °C (e.g., about 80 °C, about 90 °C, about 100 °C, about 110 °C, or about 120 °C) for about 5 to about 20 minutes (e.g., about 5, about 8, about 10, about 12, about 15, or about 20 minutes). In yet other embodiments, the heating can heat other layers of the PSC (or the PSC in the making). In still other embodiments, the heating does not significantly heat other layers of the PSC (or the PSC in the making). In certain embodiments, the heating can remove some or all of the one or more functionalizing compounds. In other embodiments, removing some of the one or more functionalizing compounds occurs during the heating step and removing more (e.g., removing the remainder of the the one or more functionalizing compounds, leftover from the heating step) of the the one or more functionalizing compounds occurs during removing step (e.g., as described below). In some instances, the heating does not remove any of the one or more functionalizing compounds. In other embodiments, the solvent during heating does not degrade (e.g., does not significantly and/or detrimentally degrade) the perovskite layer.

In some embodiments, the removing step occurs, can be any suitable method for removing some or all of the one or more functionalizing compounds, and removes some or all of the one or more functionalizing compounds (e.g., removing acetate or propionate). In certain embodiments, the removing some or all of the one or more functionalizing compounds occurs by intense pulsed light (IPL), by further heating (e.g., using hot plates, ovens (e.g., convective ovens), or IPL) (e.g., heating comprises heating at about 80 °C to about 120 °C (e.g., about 80 °C, about 90 °C, about 100 °C, about 110 °C, or about 120 °C) for about 5 to about 20 minutes (e.g., about 5, about 8, about 10, about 12, about 15, or about 20 minutes)), or both. In other embodiments, the solvent during removing does not degrade (e.g., does not significantly and/or detrimentally degrade) the perovskite layer.

In certain embodiments, the perovskite layer can be any suitable perovskite layer (e.g., a perovskite film). In other embodiments, the perovskite layer can comprise one or more of CH₃NH₃PbX₃, CH₃NH₃PbI₃, H₂NCHNH₂PbX₃, CH₃NH₃SnX₃, or Csₐ(CH₅NH₃)_{b}(CH₃NH₃)_{c}PbI_{3(1-y)}Br_{3y} where X is a halogen (e.g., iodide, bromide or chloride) which can be the same or different between or within each formula, a can be about 0 to about 0.5, b can be about 0 to about 0.8, c can be about 0 to about 0.8 and y can be about 0 to about 1. Other suitable perovskite layers (e.g., perovskite films) include those disclosed in U.S. Pat. No. 10,950,794 issued Mar. 16, 2021, which is herein incorporated by reference in its entirety.

In some embodiments, the PSC is a p-i-n type device. In other embodiments, the PSC is an n-i-p type device. Examples of various layers (and their methods of making them), such as HTLs or ETLs, in these devices can be found, for example in (a) Pitchaiya et al. (2020) “A review on the classification of organic/inorganic/carbonaceous hole transporting materials for perovskite solar cell application” Arab. J. Chem., Vol. 13, pp. 2526-2557 (which is herein incorporated by reference in its entirety) and (b) Foo et al. (2022) “Recent review on electron transport layers in perovskite solar cells” International Journal of Energy Research, 2022, pp. 1-11 (which is herein incorporated by reference in its entirety).

In other embodiments, the PSC is a flexible PSC. Examples of flexible PSC and their methods for making them can be found, for example, in (a) Tang et al. (2021) “Recent progress of flexible perovskite solar cells” Nano Today, Vol. 39, Article 101155 (which is herein incorporated by reference in its entirety) and (b) Di Giacomo (2016) “Progress, challenges and perspectives in flexible perovskite solar cells” Energy and Environmental Science, 2016, Vol. 9, pp. 3007-3035 (which is herein incorporated by reference in its entirety).

In certain embodiments, the perovskite layer can be part of a structure that further comprises one or more of an anode (e.g., any suitable anode such as ITO/glass or FTL/glass); a hole transport layer (HTL) (e.g., any suitable HTL, such as PTAA or NiOₓ); or a cathode (e.g., any suitable cathode, such as Fe, C, Ni, Pt, Ag, Al, or Cu).

In other embodiments, the perovskite layer can be part of a structure that further comprises one or more of an anode (e.g., any suitable anode such as ITO/glass or FTL/glass); an electron transport layer (ETL) (e.g., any suitable ETL, such as SnO₂, Tio₂, or ZnO); or a cathode (e.g., any suitable cathode, such as Fe, C, Ni, Pt, Ag, Al, or Cu).

In some embodiments, the method further comprises adding a cathode. Any suitable method of adding a cathode can be used, including but not limited to, screen printing, thermal evaporation, sputtering, or atomic layer deposition. In certain embodiments, the method of adding a cathode comprises thermal evaporation. The cathode that is added can be any suitable cathode, including but not limited to, Fe, C, Ni, Pt, Ag, Al, or Cu. In other embodiments, the cathode is Ag, Al, or Cu.

In certain embodiments, the PSC has an open circuit voltage (Voc) of from about 0.7 V to about 1.3 V or from about 0.8 V to about 1.1 V (e.g., about 0.7, about 0.8, about 0.9, about 1.0, about 1.1, about 1.2, or about 1.3 V).

In some embodiments, the PSC has a fill factor (FF) of from about 35 to about 80% or from about 39 to about 77% (e.g., about 35, about 40, about 45, about 50, about 55, about 56, about 57, about 58, about 59, about 60, about 61, about 62, about 63, about 64, about 65, about 70, about 75, or about 80%).

In certain embodiments, the PSC has a current density (J_{sc}) of from about 10 to about 25 mA/cm² or from about 12 to about 24 mA/cm² (e.g., about 10, about 11, about 12, about 13, about 14, about 15, about 16, about 17, about 18, about 19, about 20, about 21, about 22, about 23, about 24, or about 25 mA/cm²).

In other embodiments, the PSC has a Power Conversion Efficiency (PCE) of from about 4 to about 20% or from about 4 to about 15% (e.g., about 4, about 5, about 6, about 7, about 8, about 9, about 10, about 11, about 12, about 13, about 14, about 15, about 16, about 17, about 18, about 19, or about 20%)

Some embodiments of the invention include a PSC made as disclosed herein (e.g., as disclosed above, as disclosed in original claim 1, or as disclosed in the Examples). In other embodiments, the PSC is a flexible PSC.

Other embodiments of the invention include a PSC (e.g., as disclosed herein) comprising a material selected from one or more of an organic material, a metal oxide, TiO₂, SnO₂, ZnO, NiOₓ, Zn₂SO₄, WO₃, In₂O₃, SrTiO₃, Nb₂O₅, BaSnO₃, C₆₀, C₇₀, PC₆₁BM, PC₇₁BM, or fullerene (e.g., where the material is in an electron transport layer). In certain embodiments, the material can be functionalized according to any manner disclosed herein (e.g., as disclosed above, as disclosed in original claim 1, or as disclosed in the Examples). In some embodiments, the material comprises SnO₂, functionalized SnO₂ (e.g., functionalized with acetate), or both. In other embodiments, the PSC is a flexible PSC.

Other embodiments of the invention include a PSC (e.g., as disclosed herein) comprising (a) an anode (e.g., any suitable anode such as ITO/glass or FTL/glass); (b) a hole transport layer (HTL) (e.g., any suitable HTL, such as NiOₓ, PTAA or PTAA/PFN); (c) a perovskite layer (e.g., any suitable perovskite, such as one or more of CH₃NH₃PbX₃, CH₃NH₃PbI₃, H₂NCHNH₂PbX₃, or CH₃NH₃SnX₃, where X is a halogen (e.g., iodide, bromide or chloride) which can be the same or different between or within each formula; (d) an electron transport layer (ETL) (e.g., a material selected from an organic material, a metal oxide, TiO₂, SnO₂, ZnO, Zn₂SO₄, WO₃, In₂O₃, SrTiO₃, Nb₂O₅, BaSnO₃, C₆₀, C₇₀, PC₆₁BM, PC₇₁BM, or fullerene, or a functionalized material thereof, or SnO₂ or functionalized SnO₂ (e.g., functionalized with acetate)); and (e) a cathode (e.g., any suitable cathode, such as Fe, C, Ni, Pt, Ag, Al, or Cu). In other embodiments, the PSC is a flexible PSC.

Some embodiments of the invention include a PSC (e.g., as disclosed herein) comprising (a) an anode (e.g., any suitable anode such as ITO/glass or FTL/glass); (b) an electron transport layer (ETL) (e.g., any suitable ETL, such as SnO₂, TiO₂, or ZnO); (c) a perovskite layer (e.g., any suitable perovskite, such as one or more of CH₃NH₃PbX₃, CH₃NH₃PbI₃, H₂NCHNH₂PbX₃, or CH₃NH₃SnX₃, where X is a halogen (e.g., iodide, bromide or chloride) which can be the same or different between or within each formula; (d) a hole transport layer (HTL) (e.g., a material selected from an organic material, a metal oxide, NiOₓ, or CuO, or a functionalized material thereof, or NiOₓ or functionalized NiOₓ (e.g., functionalized with acetate)); and (e) a cathode (e.g., any suitable cathode, such as Fe, C, Ni, Pt, Ag, Al, or Cu). In other embodiments, the PSC is a flexible PSC.

Other embodiments of the invention include a PSC (e.g., as disclosed herein) comprising (a) an anode (e.g., any suitable anode such as ITO/glass or FTL/glass); (b) a hole transport layer (HTL) (e.g., any suitable HTL, such as NiOₓ, PTAA or PTAA/PFN); (c) a perovskite layer (e.g., any suitable perovskite, such as one or more of CH₃NH₃PbX₃, CH₃NH₃PbI₃, H₂NCHNH₂PbX₃, or CH₃NH₃SnX₃, where X is a halogen (e.g., iodide, bromide or chloride) which can be the same or different between or within each formula; (d) an electron transport layer (ETL) (e.g., prepared as disclosed herein, such as in original claim 1 or in any of the methods disclosed herein); and (e) a cathode (e.g., any suitable cathode, such as Fe, C, Ni, Pt, Ag, Al, or Cu). In other embodiments, the PSC is a flexible PSC.

Some embodiments of the invention include a PSC (e.g., as disclosed herein) comprising (a) an anode (e.g., any suitable anode such as ITO/glass or FTL/glass); (b) an electron transport layer (ETL) (e.g., any suitable ETL, such as SnO₂, TiO₂, or ZnO); (c) a perovskite layer (e.g., any suitable perovskite, such as one or more of CH₃NH₃PbX₃, CH₃NH₃PbI₃, H₂NCHNH₂PbX₃, or CH₃NH₃SnX₃, where X is a halogen (e.g., iodide, bromide or chloride) which can be the same or different between or within each formula; (d) a hole transport layer (HTL) (e.g., prepared as disclosed herein, such as in original claim 1 or in any of the methods disclosed herein); and (e) a cathode (e.g., any suitable cathode, such as Fe, C, Ni, Pt, Ag, Al, or Cu). In other embodiments, the PSC is a flexible PSC.

The presently-disclosed subject matter is further illustrated by the following specific but non-limiting examples. The following examples may include compilations of data that are representative of data gathered at various times during the course of development and experimentation related to the present invention.

### EXAMPLES

### Example Set A—Direct Deposition of Non-Aqueous SnO₂ Dispersion by Blade Coating on Perovskite for the Scalable Fabrication of Perovskite Solar Cells

The device architecture of a perovskite solar cells (PSC) sometimes involves a perovskite absorber sandwiched between n-type and p-type semiconductors in either a planar n-i-p or an inverted p-i-n structure. The n-type semiconductor plays a role as the electron transport layer (ETL) in the extraction of the photogenerated electrons from the active perovskite material, the electron transportation to the electrode, and the blocking of hole transport during the conversion of light into electricity. Therefore, it can be desirable for ETL materials to have a suitable bandgap and proper energy alignment with the perovskite along with high electron mobility and conductivity.

The direct deposition of fully solution-processed SnO₂ onto a perovskite absorber layer in a p-i-n structure has not yet been reported. The absence of solution-processed SnO₂ ETLs in p-i-n structures can, in part, be attributed to solvent incompatibility between the SnO₂ and perovskite. The library of the perovskite compatible solvents is limited and excludes highly polar solvents that are typically used to prepare SnO₂ dispersions. This is further complicated when using scale-up coating techniques, such as blade coating, where the evaporation kinetics result in prolonged exposure of the perovskite to solvent. Dispersions of metal oxides that are more amenable to blade coating onto a perovskite should therefore be prepared using nonpolar or less-polar organic solvents.

In this example, we report the direct deposition of a SnO₂ thin film as an ETL on perovskite in p-i-n device structure by blade coating under ambient conditions. To enable the direct deposition of SnO₂ on the perovskite, SnO₂ nanoparticles synthesized using the sol-gel method were functionalized with acetic acid to obtain particles of tin oxide acetate (SnO₂-A). The functionalization of SnO₂ with acetate enables the formation of a stable colloidal dispersion of SnO₂-A in the anhydrous ethanol, which was directly deposited on the perovskite film. The SnO₂ based device exhibited an average PCE of 12.27% with a champion PCE of 14.1%. The devices maintained 95.8% of the average initial PCE after 40 days.

### Results and Discussion

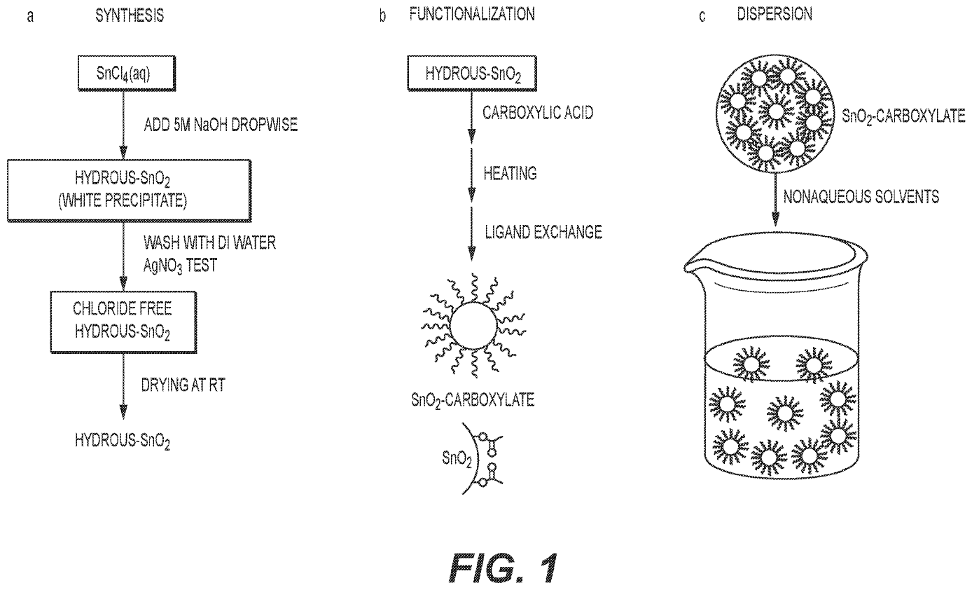

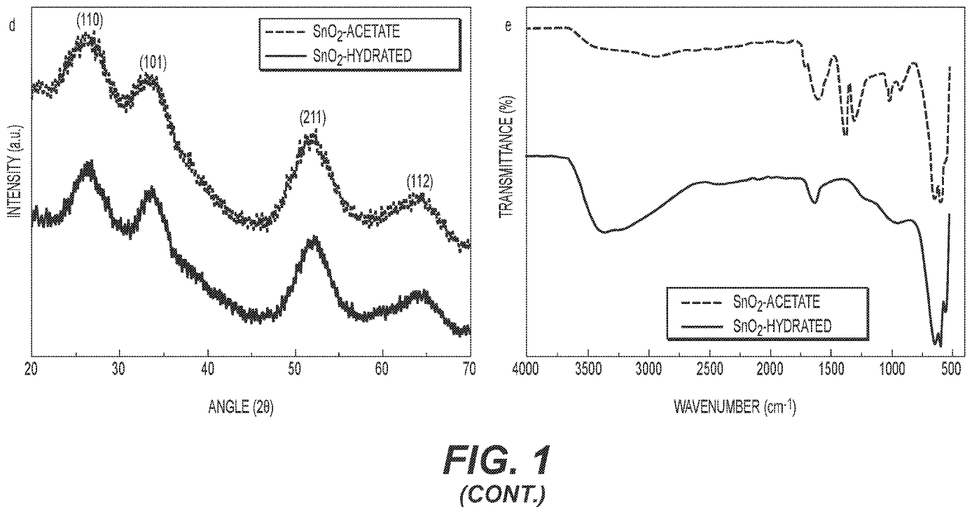

A perovskite compatible SnO₂ ink was prepared by functionalization of SnO₂ nanoparticles to enhance dispersibility in non-aqueous solvents (FIG. 1a-1c). Hydrous-SnO₂ was prepared from stannic chloride and sodium hydroxide according to established literature procedures (Fuller et al., The catalytic oxidation of carbon monoxide on tin (IV) oxide. J. Catal. 1973, 29, 441-450; McManus et al., Highly soluble ligand stabilized tin oxide nanocrystals: gel formation and thin film production. Cryst. Growth Des. 2014, 14, 4819-4826). The hydrous SnO₂ nanoparticles particles were then reacted with acetic acid to yield SnO₂ functionalized with acetate (SnO₂-A) through ligand exchange. The x-ray diffraction (XRD) patterns of hydrous-SnO₂ and SnO₂-A (FIG. 1d) both show peaks at 26°, 34°, 52°, 65° that are assigned to the (110), (101), (211), and (112) planes of the rutile crystal structure of SnO₂. The similarity of the XRD patterns indicates the ligand exchange reaction is purely a surface modification of hydrous-SnO₂ with no observable alteration of the crystal structure. The coordination of the acetate ligands to the metal oxide surface was confirmed by Fourier transform infrared (FT-IR) spectroscopy. Possible binding modes of the carboxylate ligand include monodentate, bidentate, or bridging (Deacon et al., Relationships between the carbon-oxygen stretching frequencies of carboxylato complexes and the type of carboxylate coordination. Coord. Chem. Rev. 1980, 33, 227-250). The FT-IR spectra of hydrous-SnO₂ and SnO₂-A (FIG. 1e) show a common feature at 650 cm⁻¹ associated with Sn—O stretching. The spectrum of hydrous-SnO₂ shows a broad band at 3300 cm⁻¹ and a sharp band at 1640 cm⁻¹ associated with OH stretching and bending of adsorbed water at the surface of hydrous SnO₂. The OH stretching band is reduced in SnO₂-A, which indicates the hydroxyl groups on the surface of hydrous-SnO₂ have been displaced. The coordination of acetate in SnO₂-A is confirmed by the presence of bands at 1715 cm⁻¹ and 1380 cm⁻¹ associated C═O stretching and acetate scissoring vibrations of the acetate ligand.

In contrast to hydrous-SnO₂, the SnO₂-A nanoparticles are readily dispersed in protic organic solvents such as ethanol and isopropanol. Without being bound by theory, the enhanced dispersibility of the SnO₂-A particles in protic organic solvents could be attributed to the formation of a hydrogen bonding network between the surface bonded acetate, excess acetic acid, and ethanol. In some instances, longer chain carboxylates could more effectively prevent agglomeration of the SnO₂ nanoparticles and enable the formation of a stable colloidal dispersion of SnO₂ in perovskite compatible non-polar organic solvents; in other instances, residual longer chain ligand in the ETL could hamper the charge transfer process and reduce the overall efficiency of the PSCs.

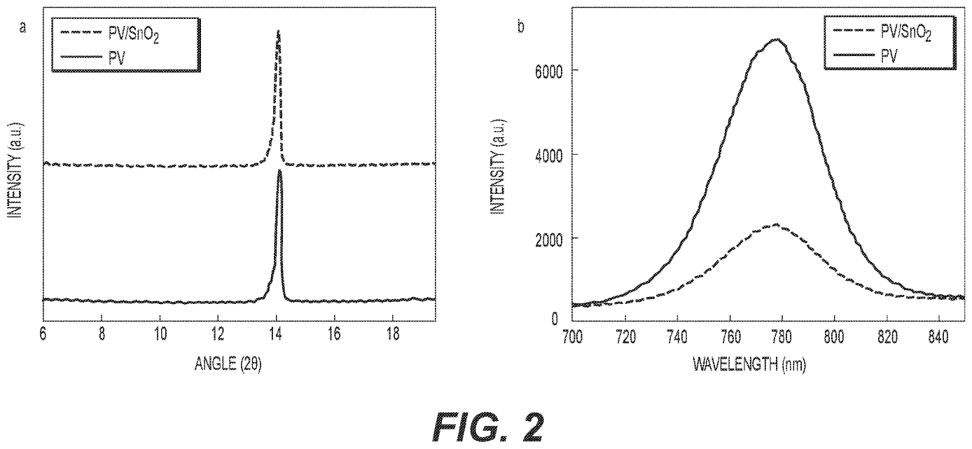

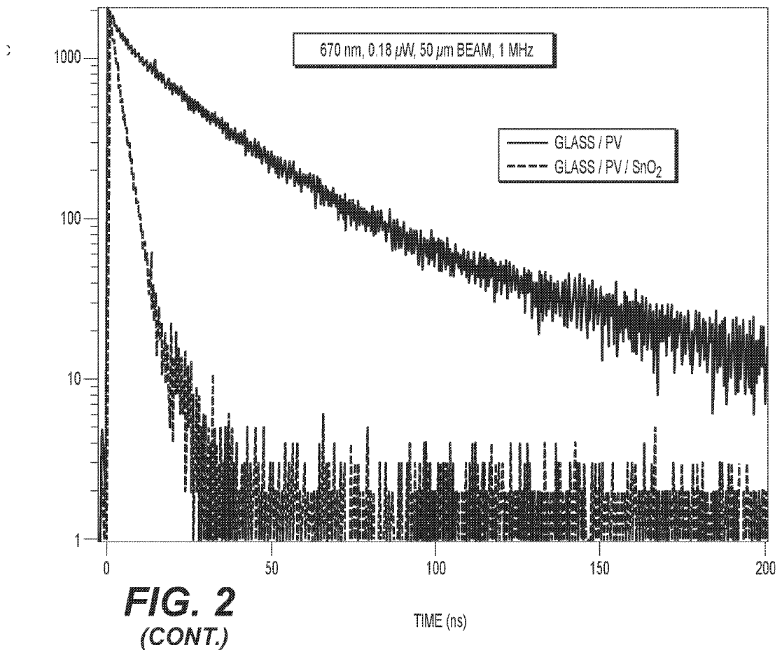

We selected to functionalize SnO₂ with a short-chain carboxylic acid even though this limits our selection of solvents for the ink formulation to anhydrous ethanol. To study the perovskite compatibility with the dispersion medium, a dispersion of SnO₂-A in anhydrous ethanol was deposited directly on the top of the perovskite layer of CH₃NH₃PbI₃ (MA=methylammonium) via blade coating. The XRD patterns of perovskite before and after deposition of SnO₂ on the perovskite are shown in FIG. 2a. The XRD pattern of the perovskite prior to deposition shows a single prominent peak at 14.1° as expected for CH₃NH₃PbI₃. The XRD pattern is unchanged after deposition of the SnO₂ indicating the perovskite layer remains intact. Had moisture-assisted degradation occurred, an additional peak at 12.7° would be observed due to the formation of PbI₂. The XRD patterns confirm that a SnO₂-A dispersion in anhydrous ethanol can be directly dispensed on the perovskite and deposited without any detectable degradation of the perovskite surface.

The dynamics of the charge carrier activity of the solution phase deposited SnO₂ layer on perovskite were studied employing photoluminescence (PL) and time-resolved PL (TRPL) spectroscopy. The steady-state PL spectra of the perovskite and perovskite/SnO₂ on a glass substrate are shown in FIG. 2b. The photoluminescence of the perovskite is strongly quenched in presence of SnO₂-A indicating a significant drop in the charge carrier density, which is consistent with efficient charge transfer from the perovskite layer to the ETL. The TRPL measurements of the perovskite before and after deposition of SnO₂-A on the perovskite supports the result of PL analysis. In FIG. 2c, the TRPL spectra, taken from the glass side, of the glass/perovskite and glass/perovskite/SnO₂-A samples show a significant decrease in the photoluminescence lifetime after deposition of the SnO₂-A. This decrease in photoluminescence lifetime confirms the effective charge extraction by the ETL from the perovskite absorber layer.

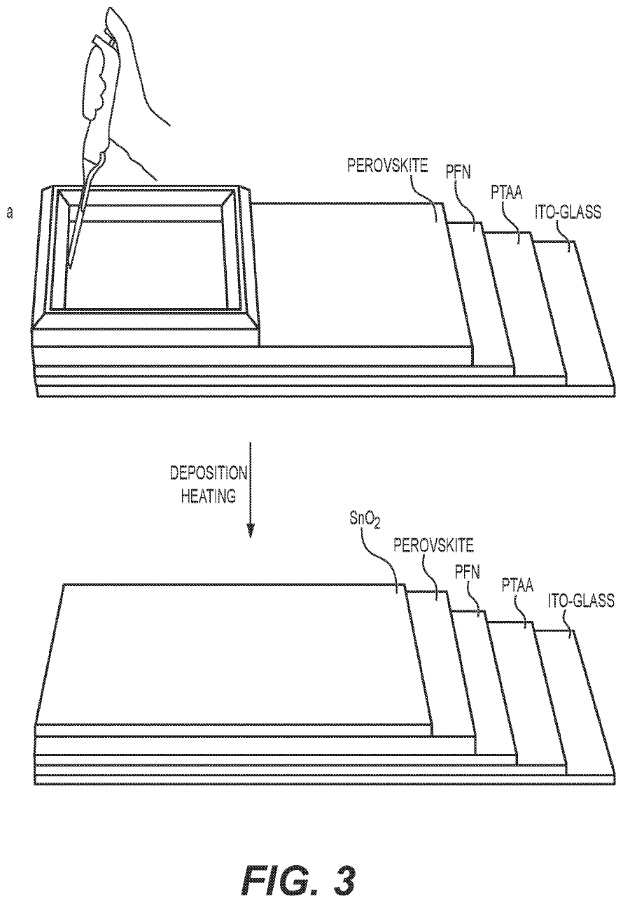

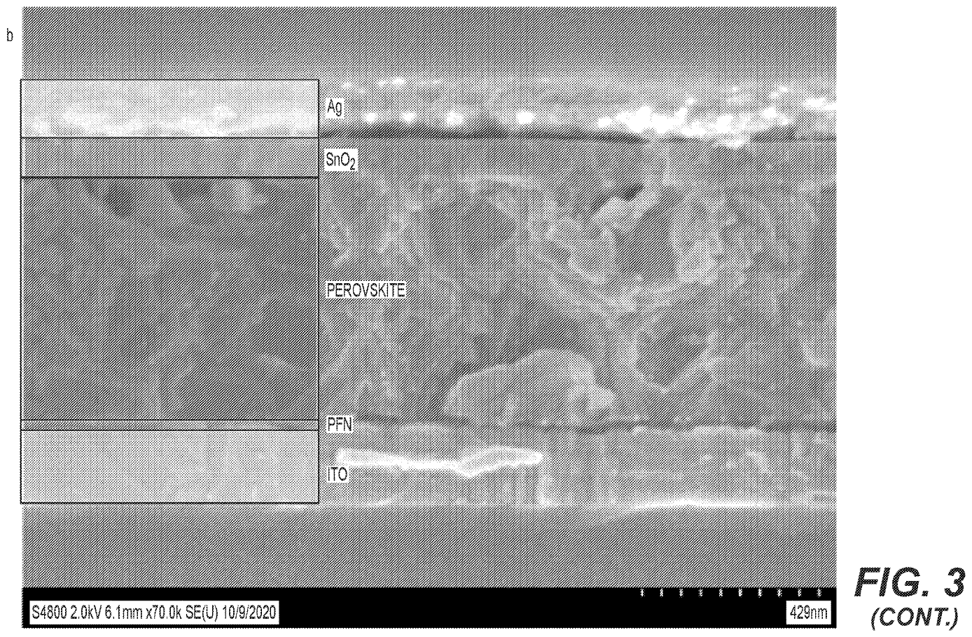

Based on the encouraging XRD, PL, and TRPL results, we fabricated PSCs with a p-i-n architecture employing SnO₂-A as the ETL. A series of planar PSCs were fabricated on indium tin oxide (ITO) coated glass with a polytriarylamine (PTAA) hole transport layer (HTL) and a poly [(9,9-bis(3′-(N,N-dimethylamino) propyl)-2,7-fluorene)-alt-2,7-(9,9-dioctylfluorene)] (PFN) interfacial layer. The overall device architecture is ITO/PTAA/PFN/CH₃NH₃PbI₃/SnO₂-A/Ag. A schematic representation of device architecture is showing in FIG. 3a, which highlights the solution-phase blade coating of SnO₂-A as the ETL on the top of the perovskite. The PTAA, PFN, and CH₃NH₃PbI₃ layers were also deposited using blade coating at ambient conditions. The SnO₂-A layer was annealed for 10 min at 100 °C to remove solvents, and finally, silver was thermally evaporated as a top contact layer. The annealing process was optimal at 100 °C and 10 min.

The deposition of SnO₂-A on the fully converted perovskite yields a uniform layer with a reflective surface. FIG. 3b shows cross-sectional scanning electron microscopy (SEM) image of the proposed p-i-n device structure. Each of the individual layers can be clearly identified. Notably, there is no visible physical deformation of the perovskite layer due to the deposition of the SnO₂-A ink directly on the perovskite. Additionally, the SnO₂-A layer is compact, uniform, and without pinholes. The optimized thickness of the SnO₂ ETL was measured to be 36.7±3.4 nm.

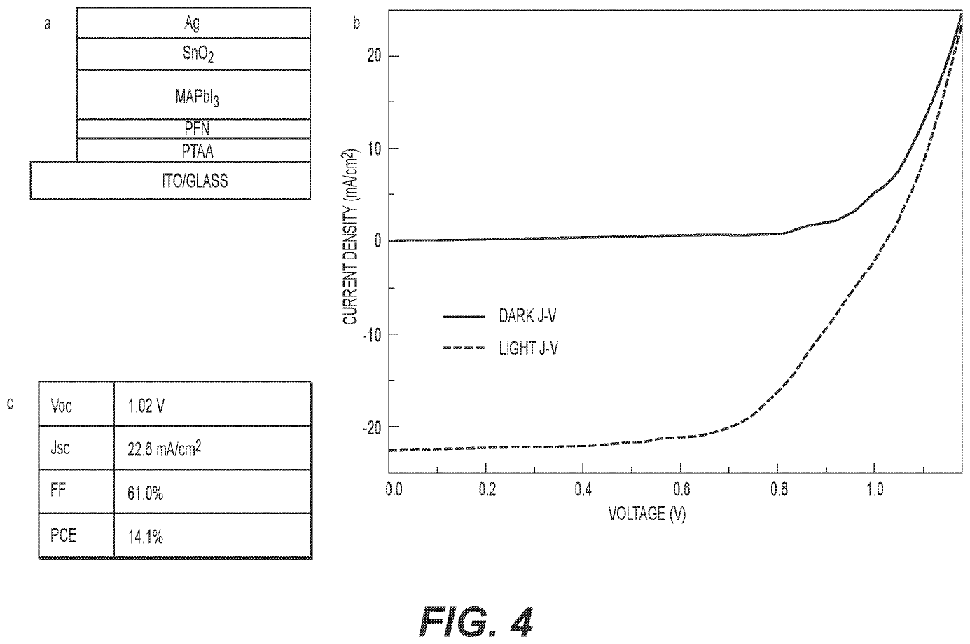

The J-V characteristics of the fabricated cells were measured under one sun condition (AM 1.5G, 100 mW/cm²) and their corresponding photovoltaic parameters including power conversion efficiency (PCE), fill factor (FF), short-circuit current density (J_{sc}), and open-circuit voltage (V_{oc}) were recorded. The champion device exhibited a PCE of 14.1% with a J_{sc} of 22.61 mA/cm², a V_{oc} of 1.023 V, and a FF of 61% (FIG. 4). As a comparison, a standard device with the device architecture ITO/PTAA/PFN/CH₃NH₃PbI₃/C₆₀/BCP/Ag (BCP=bathocuproine) was fabricated and evaluated under the same conditions. The standard device yielded a PCE of 15.11% with a J_{sc} of 18.88 mA/cm², a V_{oc} of 1.024, and a FF of 76.76% (data not shown). Both devices showed remarkably similar V_{oc} values, which would indicate that the SnO₂-A is effective for charge collection. However, the SnO₂-A device had a lower FF as compared to the control device, which may suggest charge recombination at the interface or a higher ETL thickness. Interestingly, the J_{sc} value is higher for the SnO₂-A device, which may be an artifact of the perovskite layer thickness.

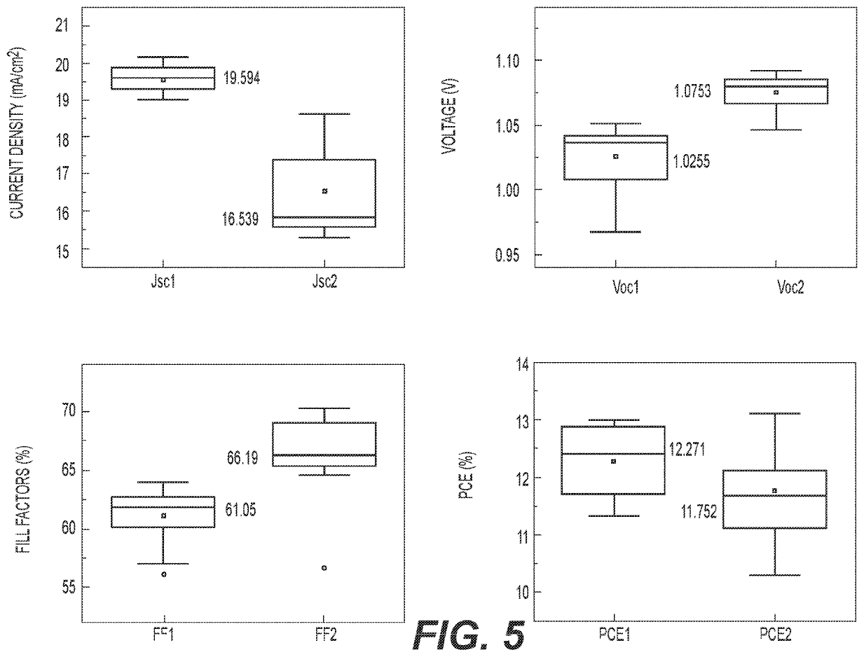

To understand the stability of the fabricated device, sample devices were stored in a nitrogen flow box after initial J-V measurements were recorded. The devices were stored without any encapsulation and the J-V characteristics were re-evaluated after 40 days. FIG. 5 shows the device performance statistics of the stability test. After 40 days, 95.8% of the average initial efficiency was retained. The loss of efficiency is mainly due to a decrease in J_{SC}, which decreased by 15.59% on average. Interestingly, the average V_{oc} and FF values increased by 4.85% and 8.42%, respectively, after storage.

### Conclusions

In summary, the solution phase deposition of a non-aqueous dispersion of SnO₂ nanoparticles directly onto a CH₃NH₃PbI₃ perovskite by a blade coating technique was demonstrated on a p-i-n device architecture. The acetate functionalized nanoparticles, SnO₂-A, were synthesized using an aqueous reaction pathway that allowed for the formulation of a stable dispersion in a anhydrous ethanol. There was no observation of a PbI₂ peak in the XRD spectrum after the deposition of the ink on CH₃NH₃PbI₃ indicating that there is no observable damage to the perovskite thin film. The photoluminescence results demonstrated that the electrons are being transported from the perovskite layer and the cross-sectional SEM show a smooth interface between the CH₃NH₃PbI₃ and SnO₂ films. The champion PSCs exhibited a PCE of 14.1% with an active area of 0.25 cm² and maintained 95.8% of this after 40 days.

### Experimental Section

### Synthesis of Hydrous-SnO₂

The tin oxide nanoparticles were prepared using sol-gel methods by neutralizing aqueous tin chloride solution with sodium hydroxide (McManus et al., Highly soluble ligand stabilized tin oxide nanocrystals: gel formation and thin film production. Cryst. Growth Des. 2014, 14, 4819-4826). In general, a 0.5 M aqueous solution of SnCl₄ was prepared by dropwise addition of anhydrous SnCl₄ to deionized (DI) water. To the vigorously stirred aqueous solution of SnCl₄, freshly prepared 5M NaOH solution in DI water was added dropwise until the pH reached pH 6.5. The resulting white precipitate of hydrous-SnO₂ was aged for 12 hours, collected by centrifugation, and washed repeatedly by dispersion in DI water/centrifugation until the aqueous layer was chloride free. The washed hydrous-SnO₂ tin oxide particles were dried at room temperature for 24 hours. The formation of SnO₂ was confirmed by XRD analysis. The actual mass of SnO₂ present on the hydrous SnO₂ was calculated to be 70% from TGA analysis.

### Synthesis of SnO₂-A and ink formulation

The acetate functionalized nanoparticles, SnO₂-A, were prepared based on the literature procedure (McManus et al., Highly soluble ligand stabilized tin oxide nanocrystals: gel formation and thin film production. Cryst. Growth Des. 2014, 14, 4819-4826). In general, hydrous-SnO₂ and glacial acetic acids were mixed in a 1:1 mass: volume ratio. In a typical preparation, 4 grams of hydrous-SnO₂ were mixed with 4 mL of glacial acetic acid. The mixture was then heated at reflux for one hour in a closed container. The mixture initially formed a milky white colloidal dispersion that became colorless and transparent upon formation of SnO₂-A. If the reaction mixture does not become completely colorless and transparent, the undissolved hydrous-SnO₂ can be removed via centrifugation. The percentage of SnO₂ in the solution was determined from TGA analysis. An aliquot of the SnO₂-A solution was dispersed in anhydrous ethanol to make an ink that contains 2% (m/v) SnO₂ suitable for deposition on directly on perovskite by blade coating. For XRD and FT-IR analysis, the initial SnO₂-A solution was transferred to an evaporating dish and the solvent was evaporate overnight. The solid product was dried in a vacuum oven at 100 °C for 2 hours prior to analysis.

### Device Fabrication

A pre-ITO-coated glass substrate was cut into 1 in.×2 in. pieces and they were cleaned using Liquinox detergent solution, acetone, isopropanol, and a nitrogen flush. The cleaned glass substrates were treated with UV-Ozone for 15 mins immediately before the sequential deposition of PTAA, PFN, CH₃NH₃PbI₃, and SnO₂-A by blade coating in an ambient environment. A PTAA solution was prepared by dissolving 8 mg of PTAA in 1 ml of toluene. A 12 μL aliquot of the PTAA solution was used for blade coating with a blade gap of 100 μm at a coating speed of 10 mm/sec, followed by heating at 100 °C for 10 mins and then cooled down to room temperature. Next, 12 μL of a 0.4 mg/mL PFN solution in methanol was blade coated on the PTAA layer at a coating speed of 7.5 mm/sec with a blade gap of 100 μm. The perovskite precursor solution was prepared by dissolving methylammonnium iodide and PbI₂ in a mixture DMF:DMSO:NMP with a volume ratio of 0.91:0.07:0.02 to get a 1.2 M solution (Ouyang et al., Toward scalable perovskite solar modules using blade coating and rapid thermal processing. ACS Appl. Energy Mater. 2020, 3, 3714-3720). A 20 μL aliquot of the perovskite precursor solution was deposited by blade coating with a blade gap of 150 μm and at a coating speed of 7.5 mm/sec. Immediately after the deposition of perovskite precursor solution, the wet film was pre-dried using an N₂ air knife followed by hotplate annealing at 140 °C for 2 mins. Finally, 20 μL of the SnO₂-A dispersion in anhydrous ethanol was deposited on the perovskite with a blade gap height of 100 μm and at the coating speed of 7.5 mm/sec, followed by annealed at 100 °C for 10 min. The fabrication of PSCs having a device architecture of glass-ITO/PTAA/PFN/CH₃NH₃PbI₃/SnO₂-A/Ag was completed by depositing 100 nm of silver on the SnO₂-A ETL employing thermal evaporation. After silver deposition, devices were mechanically scribed into an active area of 0.25 cm².

### Physical Methods

Powder x-ray diffraction (PXRD) patterns were measured using a Bruker D8 Discover X-ray diffractometer. Infrared spectra were collected using a Thermo Nicolet Avatar 360 FT-IR with Smart iTR. The cross-sectional SEM images were recorded using a JEOL 7000field-emission scanning electron microscope (SEM). PL analysis was carried out using a Renishaw in Via Raman microscope with a CCD detector and a 632 nm He—Ne laser source. The current density-voltage (J-V) characteristics of devices were measured using a Class AAA solar simulator having a Xenon arc lamp with one sun condition (AM1.5G, 100 mW/cm²). Prior to the device measurements, the solar simulator was calibrated using a NREL-certified Si reference cell. Devices were tested from 1.2 to 0 V at a scan rate of 100 mV/s with step size of 10 mV.

### Example Set B—Solvation of NiOₓ for Hole Transport Layer Deposition in Perovskite Solar Cells (PSC)

A series of nickel oxide (NiOₓ) inks, in the perovskite antisolvent chlorobenzene (CB) containing 15% ethanol, were prepared for the fabrication of p-i-n perovskite solar cells by blade coating. The inks included triethylamine (Et₃N) and alkyl xanthate salts as ligands to disperse NiOₓ particle aggregates and stabilize suspension. A total of four inks were evaluated: 0X (Et₃N with no alkyl xanthate), 4X (Et₃N+potassium n-butyl xanthate), 12X (Et₃N+potassium n-dodecyl xanthate), and 18X (Et₃N+potassium n-octadecyl xanthate). The inks were characterized by UV-visible spectroscopy and FT-IR spectroscopy and the resulting films analyzed by thermogravimetry and scanning electron microscopy. Devices prepared using the 0X ink resulted in a peak power conversion efficiency (PCE) of 14.47% (0.25 cm²) and 9.96% (1 cm²). The 0X devices showed no significant loss of PCE after 100 days in a nitrogen flow box. Devices prepared with inks containing alkyl xanthate ligand had lower PCE that decreased with decreasing chain length, 18X>12X>4X.

In this example, we report the development of soluble NiOₓ particles for the solution phase deposition of inorganic HTLs for use in scalable PSCs. Some PSC devices include a perovskite active layer between an electron transport layer (ETL) and a hole transport layer (HTL) on an indium tin oxide (ITO) or fluorine-doped tin oxide (FTO) substrate with a metal (Ag or Au) top electrode. The architecture of the device can be n-i-p or p-i-n depending on the relative ordering of the ETL (n), perovskite (i), and HTL (p). The HTL and ETL layers can have roles in improving the photovoltaic performance of PSCs through modulation of charge carrier recombination and charge extraction capabilities.

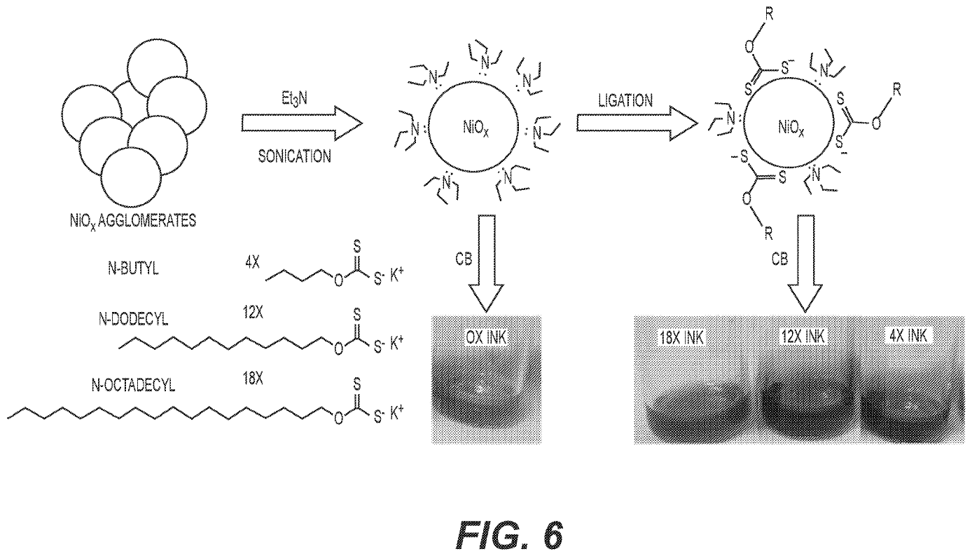

In some aspects of this example, the development of chlorobenzene (CB) compatible NiOₓ nanoparticles is explored using ligands with variable alkyl chain lengths in order to obtain NiOₓ films with a reduced presence of residual organic ligands. A series of inks with alkyl xanthates (ROCS₂⁻) with various chain lengths and triethylamine (Et₃N) have been prepared (FIG. 6). Xanthates were selected as an alternate to carboxylates due to their excepted enhanced lability, while still being structurally comparable with carboxylates, and ease of preparation from low cost materials. The Et₃N additive was included as it was found to promote stability of the dispersion. One goal of this example was to identify the possible alkyl chain length to obtain CB stable inks for the fabrication of functional PSCs by blade coating.

### Experimental Section

### Materials and Methods

The NiOₓ particles were synthesized by known solvothermal methods (Beach et al, Chem. Phys. 2009, 115, 371-377). Briefly, nickel acetylacetonate (Ni(acac)₂) was dissolved in methyl ethyl ketone (MEK) to form a 0.1 M solution. The resulting solution was sparged with N₂ gas for 30 minutes and then sealed in a Teflon lined Parr reactor. The reactor was heated at 225 °C for 16-18 hours. The reactor was cooled to room temperature and the resulting product isolated from the solution by centrifugation for 15 minutes. The crude NiOₓ product was cleaned by repeated suspension/isolation with MEK and isopropanol (IPA). The potassium xanthates salts were prepared from potassium hydroxide, carbon disulfide, and the appropriate alcohol using reported methods. Xanthates with 4- and 12-carbon chains were isolated as yellow solids as described by Carta (Carta et al., J. Med. Chem. 2013, 56, 4691-4700). The 18-carbon chain xanthates was prepared as reported by Sawant as white solids (Sawant et al., Langmuir 2001, 17, 2913-2917). The sodium carbonate salts were prepared as flaky, white solids from sodium phenoxide, carbon dioxide, and the appropriate alcohol according to the method reported by Ichiro (Ichiro et al., B. Chem. Soc. Jpn. 1976, 49, 2775-2779).

### Physical Methods

Powder x-ray diffraction (PXRD) patterns of NiOₓ powders were measured using Bruker Discovery D8 High resolution X-ray diffractometer with Cu Kα radiation (1.54 Å, 40 KV, at a step speed of 0.7 sec/step, 25°-85°). Films were deposited using an air knife equipped Zehntner ZAA 2300 Automatic film applicator and ZUA 2000 Universal Applicator. The surface morphology of NiOₓ powder and films were characterized using a top-view scanning electron microscope (SEM, Thermo-Fisher Scientific Apreo C LoVac FESEM). Film thickness and roughness were measured using a Veeco Dektak 8M Profilometer. Absorption spectra NiOₓ were measured using a UV-visible spectrophotometer (Agilent 8453). The stability and particle size of NiOₓ inks were characterized by performing Zeta potential measurements (Brookhaven Instrument Corporation 90Plus Particle Size Analyzer). Infrared spectra of organics and inks were collected using a Thermo Nicolet Avatar 360 FT-IR with Smart iTR. Thermal decomposition of xanthates and associated inks was identified by thermogravimetric analysis (TGA, Differential Scanning calorimeter Q20 30 °C-800 °C, 20 °C/min). The current density-voltage (J-V) characteristics of devices were measured using a Class AAA solar simulator having a Xenon arc lamp with one sun condition (AM1.5G, 100 mW/cm²). Prior to the device measurements, the solar simulator was calibrated using a NREL-certified Si reference cell. Devices were tested from 1.2 to 0 V at a scan rate of 100 mV/s with step size of 10 mV.

### Device Fabrication

Devices with the following p-i-n architecture were fabricated: glass/ITO/NiOₓ/PFN/MAPbI₃/C₆₀/BCP/Ag where PFN and BCP are poly [(9,9-bis(3′-(N,N-dimethylamino) propyl)-2,7-fluorene)-alt-2,7-(9,9-dioctylfluorene)] and bathocuproine, respectively. The ITO coated glass was cut into 1″×2″ substrates that were cleaned by N₂ flush, followed by UV-O₃ treatment for 15 minutes and a second N₂ flush. No further steps were taken to clean the ITO substrates. The cleaned ITO substrates were immediately used for sequential deposition of NiOₓ, PFN, and MAPbI₃ by blade coating. The NiOₓ inks were prepared by sonication of NiOₓ particles (20 mg) in 200 μL of a 3:1 (v/v) Et₃N/EtOH mixture for 60 minutes at 65 °C in a closed vial. The resulting suspension was diluted with 700 μL CB and 100 μL EtOH to make a 20 mg/mL NiOₓ solution. For NiOₓ inks containing xanthate ligands, 0.125 eq. of ligand was added to the CB in the dilution step. After dilution, the suspensions were sonicated with heating at 65 °C. During this step, inks containing xanthate ligands underwent a color change as shown in FIG. 6. The hot ink suspensions were filtered through 0.2 μm PTFE prior to blade coating. 40 μL inch⁻² of the NiOₓ inks were deposited by blade coating using an optimized blade gap of 225 μm at a speed of 5 mm sec-1 followed by annealing on a hotplate at 300 °C for 20 minutes. Next, a layer of PFN (4 mg/mL in methanol) deposited by blade coating with a blade gap of 100 μm at a speed of 7.5 mm sec-1. Perovskite ink was prepared by dissolving PbI₂ and MAI in dimethyl sulfoxide (DMSO, 7%), N-methyl-2-pyrrolidone (NMP, 2%), and dimethylformamide (DMF, 91%) to make a 1.2M solution by gentle stirring. The perovskite was deposited by blade coating with a blade gap of 100 μm at a speed of 7.5 mm sec-1 at room temperature. After perovskite deposition, the films were dried with a N₂ knife at a pressure of 40 psi prior to annealing at 140 °C for 2 minutes. Devices were completed by thermally evaporating C₆₀, BCP, and Ag followed by mechanical scribing into an active area of 0.25 and 1 cm² cells.

Initial n-i-p devices with a glass/ITO/SnO₂/MAPbI₃/NiOₓ/Ag architecture were constructed using 20 μL inch⁻² of 3% (wt %) commercial SnO₂ nanoparticles as the ETL. Optimized SnO₂ films were deposited using blade coating with a blade gap of 100 μm blade gap at 5 mm sec⁻¹ on a 100 °C heated stage followed by annealing at 150 °C for 1 hour. All other layers were deposited in the same manner as described above.

### Results and Discussion

### Ink Formulation and Characterization

A series of NiOₓ nanoparticles have been prepared that can be suspended in chlorobenzene (CB) as inks for the preparation of hole transport layers with perovskite photovoltaics. The NiOₓ particles were initially ligated with the Lewis base triethylamine (Et₃N) to which alkyl xanthate (ROCS₂⁻) ligands were added (FIG. 6). The alky substituent on the xanthate was varied to evaluate the effect of carbon chain length on the ink properties and device performance. The various NiOₓ particles are identified based on the length of the alkyl chain as follows: 0X (no xanthate), 4X (n-butyl xanthate), 12X (n-dodecyl xanthate), 18X (n-octadecyl xanthate).

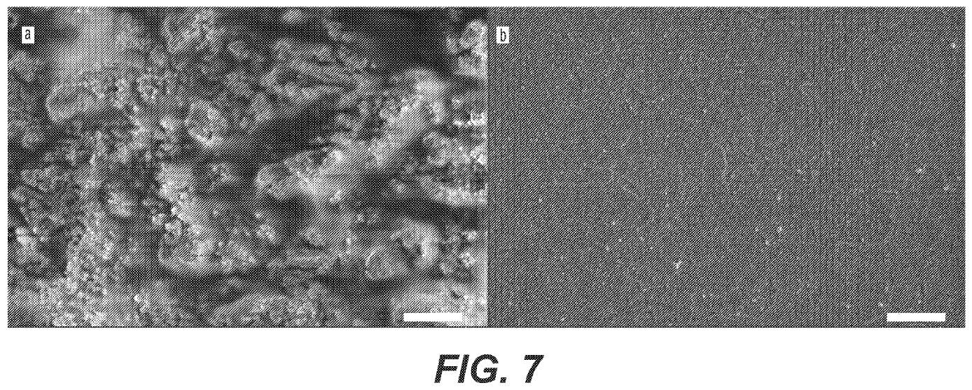

The initial NiOₓ particles were prepared by solvothermal synthesis as described by Beach (Beach et al., Mater. Chem. Phys. 2009, 115, 371-377). The identity and purity of the synthesized nanoparticles was confirmed by powder x-ray diffraction (PXRD) studies, which showed the expected peaks at 36.8° (111), 42.8° (200), 62.3° (220), 74.7° (311), 78.8° (222). From the PXRD, the crystal size was estimated to be approximately 8 nm based on the Scherrer equation. These small particles tend to agglomerate and form large aggregates in the solid phase as shown in the SEM image in FIG. 7a. The initially prepared NiOₓ nanoparticles were dispersed in a 3:1 (v/v) Et₃N/EtOH solution and subjected to sonication for one hour at 65 °C. The Et₃N, a Lewis base with a high donor number and entropic alkyl groups, was added as a weakly coordinating ligand to help break up the agglomerate and prevent re-aggregation by changing the particle surface energies and sterics. After sonication, the dispersion was diluted with a 7:1 (v/v) CB/EtOH solution to which the xanthate salt, if used, was added. The resulting ink suspension were then filtered through a 0.2 μm PTFE filter resulting in transparent suspension (FIG. 6). The SEM image of a film prepared using the 0X ink showed the formation of a uniform film (FIG. 7b) confirming the breakdown of NiOₓ aggregates into smaller nanoparticles by the Et₃N. Dynamic light scattering on the sonicated 0X ink found the particle size to be 8.3±2.1 nm, which is consistent with the PXRD size estimates.

To quantify the effect of Et₃N on the dispersion stability of the NiOₓ particles, the ζ-potential was measured for the 0X solution. The ζ-potential measures the potential difference between the dispersed particle and the medium with stable suspensions generally having values of at ±30 mV. The ζ-potential can be dependent on the composition of the particles and their chemical environment. Prior to the addition of Et₃N, the ζ-potential of the initially prepared NiOₓ particles was 6.19±3.0 mV consistent with their observed agglomeration. Addition of 15% Et₃N to yield the 0X particles increased the ζ-potential to 27.29±3.9 mV. The results indicate that Et₃N, even in the absence of additional alkyl xanthate ligands, is sufficient to stabilize the suspension of NiOₓ in CB.

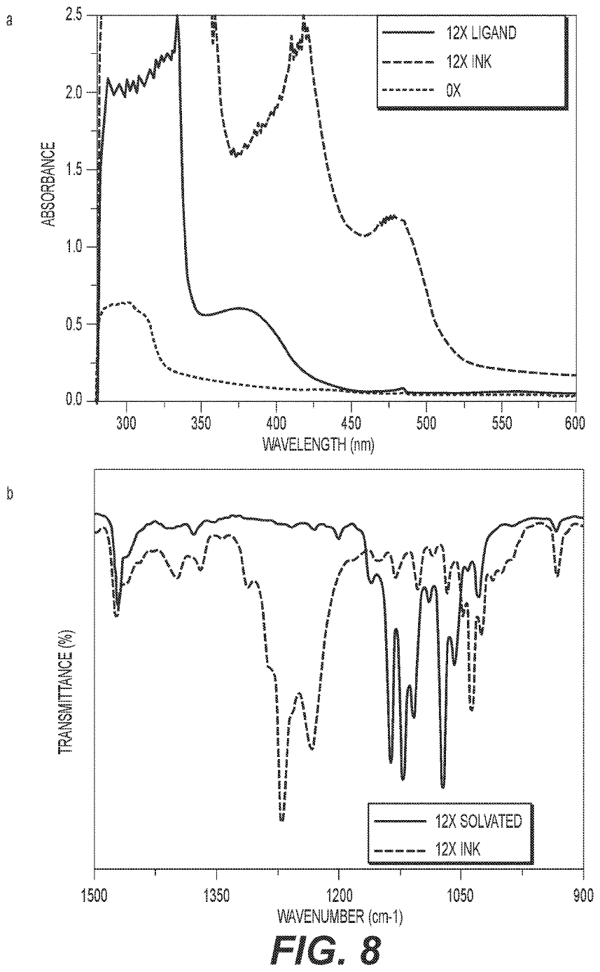

Addition of alkyl xanthate to the 0X ink results in a ligand exchange process with coordination of xanthate to the NiOₓ particles, as observed by UV-Visible spectroscopy. The 0X ink has a primary excitonic peak centered at 300 nm and the ink is visually a light tan in CB. Addition of alkyl xanthates to the NiOₓ particles yields dark brown suspensions after heating and filtration (FIG. 6). A comparison of the UV-visible spectra of the alkyl xanthates and their corresponding inks confirm the color changes are associated with coordination of the alkyl xanthates to the NiOₓ particles. The UV-visible spectra of the 12X alkyl xanthate salt in CB shows a ligand-to-ligand band at 380 nm that shifts to 420 nm upon addition of NiOₓ (FIG. 8a). Additionally, there is a new band at 480 nm in the ink associated with a ligand-to-metal charge transfer from the xanthate to the nickel. Similar bands are observed at 476 and 414 nm in molecular nickel xanthate complexes. The UV-visible spectra for the 4X and 18X xanthate salts and their respective inks show similar features (data not shown).

The coordination of the alkyl xanthate ligands to the NiOₓ particles was further confirmed by FT-IR spectroscopy. The spectrum of the 12X alkyl xanthate shows a C═S stretch at 1070 cm⁻¹ that shifts to 1030 cm⁻¹ in the ink and a C—O—C stretch at 1120 cm⁻¹ to 1230 cm⁻¹ upon addition of the NiOₓ (See FIG. 8b), additionally indicating coordination. Attempts to prepare a series of inks based on related alkyl carbonates (ROCO₂⁻) were unsuccessful due to decomposition of the alkyl carbonates upon addition to the 0X NiOₓ suspension (data not shown).

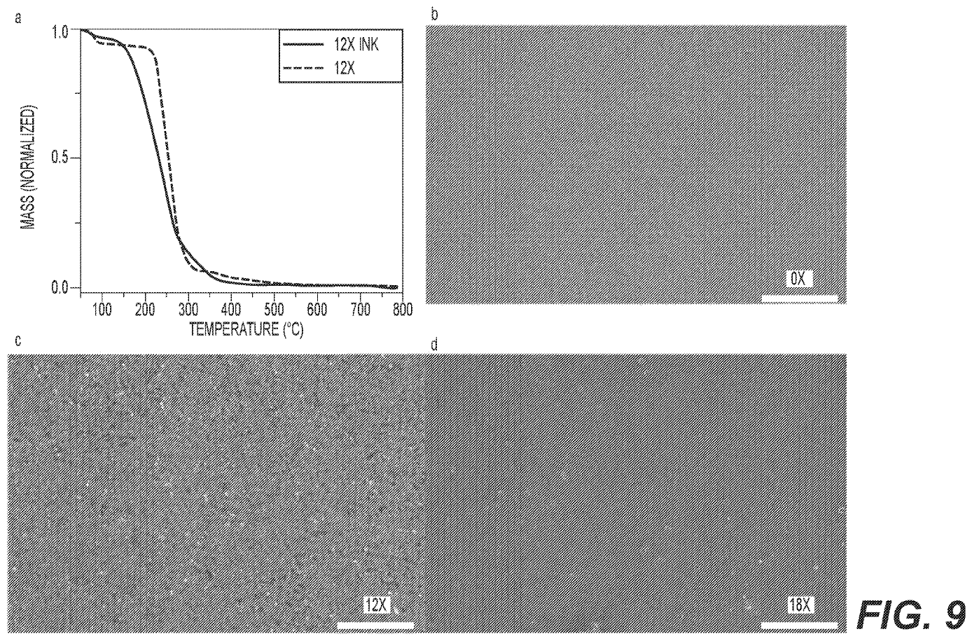

Thermal gravimetric analysis (TGA) was performed on the alkyl xanthate ligands and their corresponding inks to determine their stability under annealing conditions. Since residual long-chain compounds in the NiOₓ layer have been shown to lower the PCE of PSCs, ligands that decompose during annealing may offer an advantage. Prior TGA studies on synthesized NiOₓ particles without additional ligands yielded an annealing temperature of 300 °C (Beach et al., Mater. Chem. Phys. 2009, 115, 371-377). The TGA of the 12X salt, as a powder, shows an initial, small mass loss due to dehydration followed by a sharp, substantial mass loss associated with xanthate decomposition from 210 to 315 °C (FIG. 9a). The TGA of films prepared from 12X inks show a similar decomposition feature between 135 and 350 °C (FIG. 9a). Results for the 4X and 18X ligands and inks are similar with xanthate decomposition occurring from 210-320 °C (data not shown). Notably, all the xanthates decompose at or below NiOₓ particle annealing temperature of 300 °C indicating that under our current conditions the xanthates are fully removed from the NiOₓ films.

### Film Deposition

The 0X-18X inks were deposited as thin films on ITO glass by blade coating with a blade gap of 225 μm at a speed of 5 mm sec-1. The films were annealed at 300 °C for 20 minutes. Using these parameters, film thicknesses of approximately 40 nm, as determined with a Dektak surface profilometer, were reproducibly obtained. The roughness of the 0X film is measured to be 5.9 nm by Dektak. SEM imaging of the 0X film shows a tightly packed film with no visible pinholes (FIG. 9b). The tight packing of the film is attributed to the presence of the volatile Et₃N in the ink. The Et₃N coordinates to the NiOₓ particles in the ink to stabilize the suspension. Once the ink is deposited, evaporation of Et₃N would allow NiOₓ particles to pack closely together in the film.

For inks containing xanthate ligands, the film quality is dependent on the length of the carbon chain. The SEM image of the 18X film shows uniform coverage with the presence of some pinholes (FIG. 9d). Surface roughness is found to be about 6.5 nm. Imaging of the 12X film shows a film with significant pinholes and the presence of agglomerating particles (FIG. 9c). These defects result in a roughness of 12.9 nm. The 4X inks failed to yield a uniform film and only a few agglomerates were observed on the surface (data not shown). Without being bound by theory, the uniform coverage of the long chain xanthate ligand (18X) could be attributed to strong dispersion forces that induce alignment of the hydrophobic alkyl chains allowing tighter packing of the NiOₓ particles. Removal of the xanthate ligands during annealing results in the formation of some pinholes as the xanthates decomposes to gaseous products. Without being bound by theory, it is envisioned that the short chain xanthate ligand (4X) could be unable to induce film formation resulting in a random distribution of NiOₓ particles on the surface leading to poor film quality and significant agglomeration upon annealing. Films formed with the intermediate length xanthates (12X) show both pinholes and some particle agglomeration while still being able to form a film.

### Device Performance

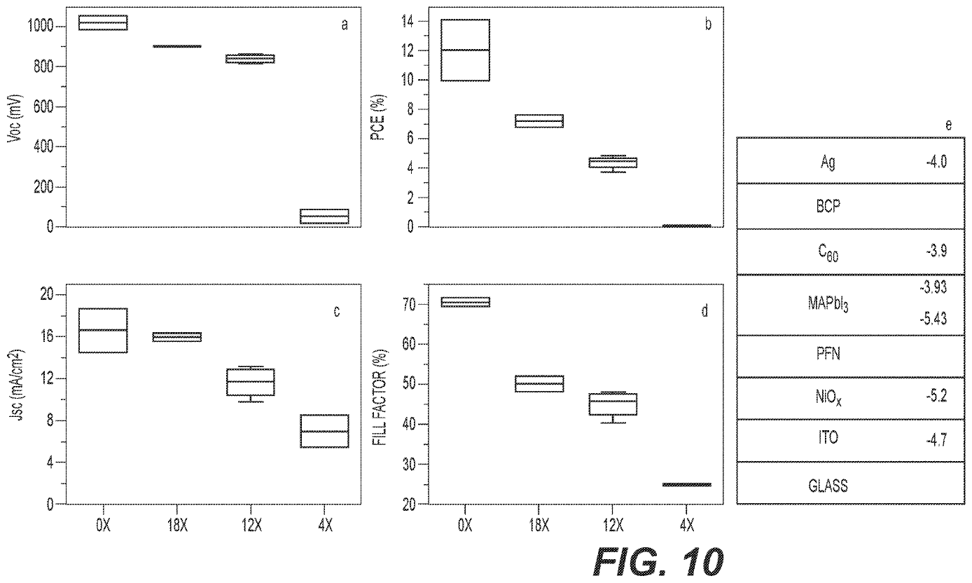

To evaluate the effect of xanthate ligands on PSC performance, a series of devices having an architecture of glass/ITO/NiOₓ/PFN/MAPbI₃/C₆₀/BCP/Ag were constructed by blade coating of the NiOₓ, PFN, and MAPbI₃ and thermal evaporation of C₆₀, BCP, and Ag. Cells were mechanically scribed into an active area of 0.25 cm² and tested under 1 sun condition. PFN was incorporated to improve the surface wetting of the perovskite deposition using known blade coating parameters. FIG. 10 shows the distribution of device performance parameters across multiple samples of the different ligand conditions investigated. The device performance results show that 0X clearly outperforms the xanthate coated particles. However, for devices containing xanthates performance decreases with decreasing xanthate chain length. The light and dark current-voltage (J-V) curves of the champion devices and their corresponding photovoltaic parameters are summarized in Table B1. The highest 0X device exhibited a PCE of 14.47%, with current density (J_{sc}) of 19.23 mA/cm², open circuit voltage (V_{oc}) of 1049.32 mV, and fill factor (FF) of 71.72%.

TABLE B1
Photovoltaic parameters of champion devices

| | Area | PCE | V_{oc} | J_{sc} | FF | Rₛ | Rₛₕ |
|---|---|---|---|---|---|---|---|
| Ink | (cm²) | (%) | (mV) | (mA/cm²) | (%) | (Ω cm²) | |
| 0X | 0.25 | 14.47 | 1049.32 | 19.23 | 71.72 | 8.0 | 728.7 |
| 18X | 0.25 | 7.61 | 891.80 | 16.22 | 52.61 | 6.9 | 316.6 |
| 12X | 0.25 | 4.86 | 817.16 | 12.44 | 47.84 | 11.9 | 326.9 |
| 4X | 0.25 | 0.19 | 89.99 | 8.64 | 25.03 | 10.3 | 11.2 |
| 0X | 1.00 | 9.96 | 970.45 | 17.81 | 57.61 | 8.5 | 615.9 |
| 18X | 1.00 | 7.51 | 968.89 | 13.95 | 55.58 | 8.4 | 573.9 |

The relative values of J_{sc} are consistent with the differences in NiOₓ film quality observed in the SEM images, which can affect the quality of the perovskite layer. The J_{sc} value is highest for 0X and decreases in films containing xanthate ligand as the chain length decrease. This is consistent with previous studies that show a decrease in J_{sc} can occur with an increasing size and density of pinholes in the HTL; also noted in previous studies, V_{oc} can be dependent on total surface coverage with a nearly constant value when there is at least 80% surface coverage. In the present study, the V_{oc} decreases from 0X to 18X to 12X consistent with decreasing surface coverage within this series, followed by a substantial drop for 4X, which performed as a photo-resistor, due to its poor film quality. Overall, the high V_{oc} and J_{sc} of the 0X device indicate a high level of uniformity in the HTL and subsequently the perovskite depositions. Variations in the J_{sc} being due to small variations in the perovskite itself but having no overall effect on the trends observed. Further confirming the significant effects of the film quality, the FF shows a nearly 20% drop from the 0X to the 18X devices. The FF is dependent on the shunt (Rₛₕ) and series (Rₛ) resistance of the device. The series resistance in these two films is similar (0X: 8.0 Ω cm² vs 18X: 6.9 Ω cm²) despite the inclusion of a long chain xanthate ligand in the 18X ink. This is attributed to removal of the xanthate ligand during the annealing step. However, the shunt resistance of the 0X film is more than twice that of the 18X film (0X: 728 Ω cm² vs 18X: 316 Ω cm²) resulting in the improved FF in the 0X device. The lower shunt resistance in the 18X device is consistent with the greater presence of pinholes noted above.

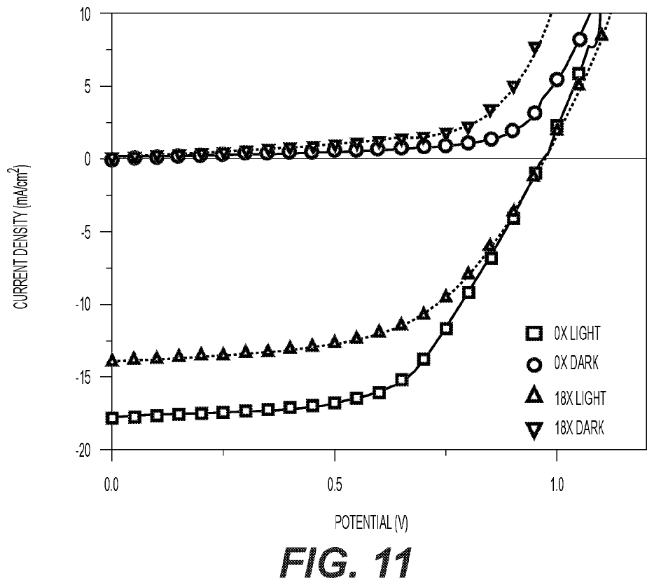

Next, 0X and 18X were evaluated as 1 cm² devices to test their applicability for large scale production. The J-V curves are shown in FIG. 11 and the data is summarized in Table B1. Notably, in the 1 cm² devices 0X and 18X have similar V_{oc}, FF, Rₛ, and Rₛₕ values. There is, however a nearly 4 mA/cm² difference in J_{SC}, between the 18X and 0X samples resulting in a greater PCE for the 0X device. The higher J_{sc} of the 0X device was also observed in the 0.25 cm² devices and can be attributed to increased presence of pinholes in the 18X film. A comparison of 0X performance in the 0.25 cm² and 1 cm² cells shows a 4.9±0.3 percent decrease in PCE due to largely due to decreases in J_{sc} and Rₛₕ attributed to the presence of more pinholes over the larger area.

The long-term stability of a 0X and 18X device was evaluated following storage in a nitrogen flow box for 100 days exposed to lab lighting. Device performance is summarized in Table B2. The 18X device shows a general degradation in quality with decreases in J_{SC}, Rₛₕ, and FF resulting in a drop in PCE after 100 days. The 0X device shows greater stability. There is a decrease in V_{oc} and FF over 100 days, but there is also an unexpected increase in J_{sc} and Rₛₕ resulting in no statistical change in PCE. Without being bound by theory, this increase could be due to the further removal of Et₃N from the device interface; Et₃N having a vapor pressure of 7.2 kPa at 20 °C would further evaporate with aging of the device. Without being bound by theory, the higher stability of the 0X device compared to the 18X device could be attributed to the quality of the NiOₓ film and the quality of the resulting perovskite to have less trap states that would lead to film degradation.

TABLE B2
Photovoltaic parameters for 0.25 cm² devices before
and after storage in nitrogen flow box for 100 days

| | PCE | V_{oc} | J_{sc} | FF | Rₛ | Rₛₕ |
|---|---|---|---|---|---|---|
| Ink | (%) | (mV) | (mA/cm²) | (%) | (Ω cm²) | |
| 0X | 10.00 | 988.01 | 14.41 | 70.25 | 3.3 | 990.7 |
| Initial | | | | | | |
| 0X | 11.16 | 956.53 | 18.11 | 64.41 | 7.3 | 1306.5 |
| 100 day | | | | | | |
| 18X | 7.61 | 891.80 | 16.22 | 52.61 | 6.9 | 316.6 |
| Initial | | | | | | |
| 18X | 5.06 | 884.13 | 14.13 | 40.57 | 6.4 | 103.0 |
| 100 day | | | | | | |

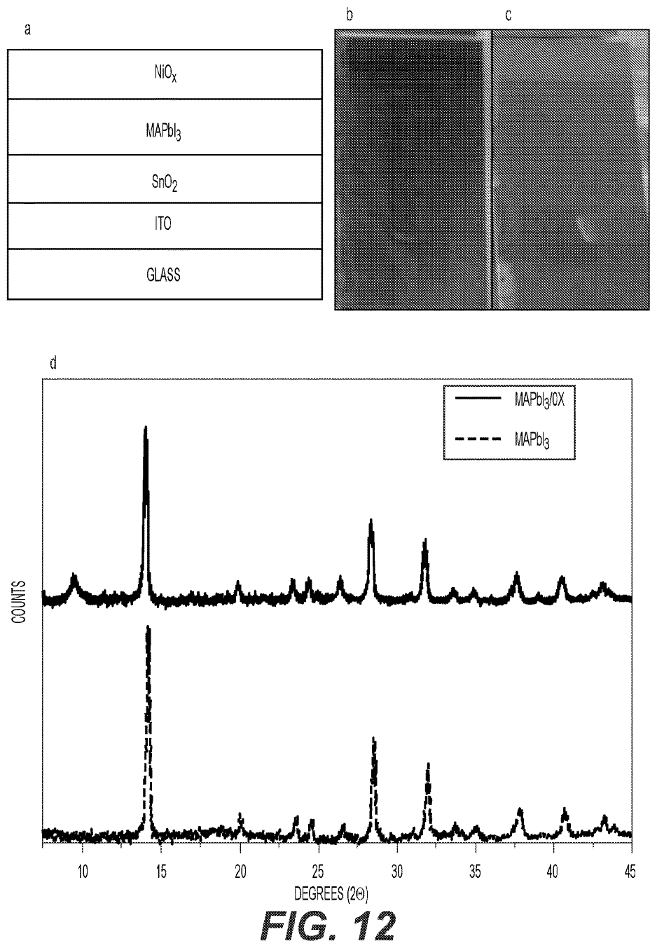

Given the performance of p-i-n devices using of the 0X ink, construction of a n-i-p device was undertaken with a glass/ITO/SnO₂/MAPbI₃/NiOₓ/Ag architecture (FIG. 12a). The ETL, HTL, and perovskite layer were deposited by blade coating using the parameters described in experimental section. Upon deposition of NiOₓ atop the perovskite the appearance of the stack shifted from a black mirror finish to a metallic blue with retention of its reflective nature (FIGS. 12b and 12c). However, no functional devices were found upon solar testing. Evaluation of the MAPbI₃—NiOₓ interface by PXRD shows the appearance of a peak at 9.5° (FIG. 12d) upon deposition of the 0X ink on the perovskite. The same peak is observed when the ink solvent mixture (CB, EtOH, Et₃N) is deposited on the perovskite (data not shown). This suggests the formation of a Et₃N adduct peak with the perovskite similar to that observed with DMSO. Notably, no peak is observed at 12.7 indicating that MAPbI₃ is not degraded to PbI₂.

### Conclusions

A series of ink formulations have been developed that successfully suspend NiOₓ nanoparticles in the perovskite antisolvent CB in mixtures containing EtOH with Et₃N (0X) or Et₃N/alkyl xanthates (4X, 12X, 18X). The carbon chain length of the alkyl xanthate was varied to probe its effect on ink performance. Although hydrophobic chelating ligands were previously used to solubilize NiOₓ for fabrication of PSCs, we found that Et₃N alone was sufficient to stabilize NiOₓ nanoparticles in solution and disperse aggregates upon sonication. In fact, the 0X ink yielded the best film quality and device performance with champion PCEs of 14.47% (0.25 cm²) and 9.96% (1 cm²). The 0X cells were stable for 100 days in a nitrogen flow box with no significant change in PCE. For PSCs containing alkyl xanthate ligands, the best film quality and device performance was obtained for 18X. Without being bopund by theory, this could be attributed to preferential ordering of the NiOₓ on the surface due to dispersion interactions of the long carbon chain and the degradation of the alkyl xanthate during thermal annealing. However, the 18X inks led to more pinholes than the 0X ink resulting in a decrease in PCE. Shorter chain alkyl xanthates had lower performance with 4X inks failing to form films. Overall, our results provide a new formulation for the preparation of NiOₓ inks in the perovskite antisolvent CB based on the volatile and weakly coordinating Et₃N ligand. This provides several advantages over non-volatile charged ligands with long carbon chains.

### Example Set C—NiOₓ and Cu Doped NiOₓ Nanoparticles

A 5 M solution of Ni(NO₃)₂·6H₂O was prepared by dissolving Ni(NO₃)₂·6H₂O in 25 mL of deionized water. While stirring vigorously a 10 M solution of NaOH was added by dropwise addition until the pH was adjusted to 10. The resulting precipitated Ni(OH)₂ was then collected by centrifuge and washed repeatedly with deionized water. After washing the Ni(OH)₂ was fully dried at 80 °C. The dry Ni(OH)₂ was then collected and annealed at 270 °C for 15 min to convert to NiOₓ. Copper doped particles where prepared in the same manner with a 5 mol % Cu(NO₃)₂·3H₂O substitution in the original Ni(NO₃)₂·6H₂O solution.

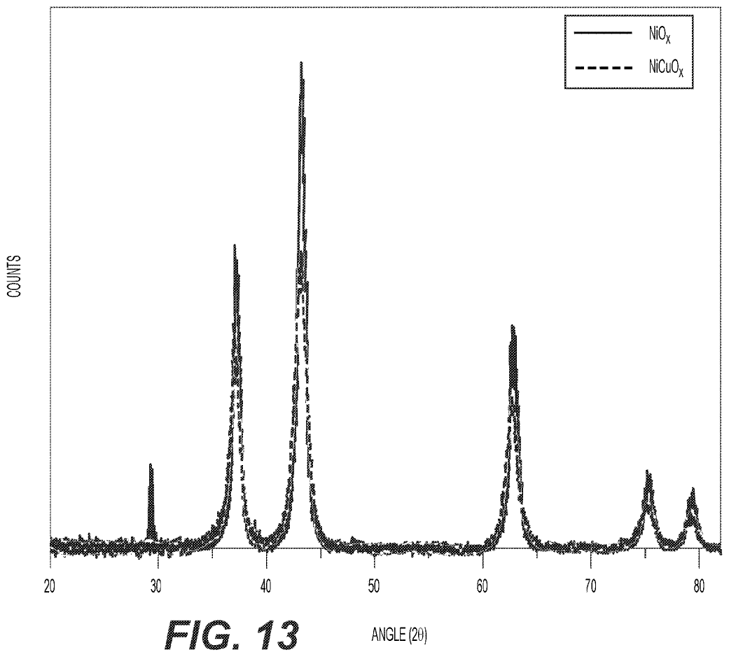

Powder x-ray diffraction confirms retention of the cubic NiOₓ structure upon addition of copper (FIG. 13). There is observed a slight loss in signal intensity indicating a lower level of crystallinity in the copper doped particles. From the Scherrer equation the crystal domain in the copper doped particles is found to be 6.9 nm while the crystal domain in the undoped is 11.2 nm. The peak at 29° is associated with nitrate and further washing was able to successfully remove it. Composition was confirmed by X-ray fluorescence to be 5.6±1.3% Cu.

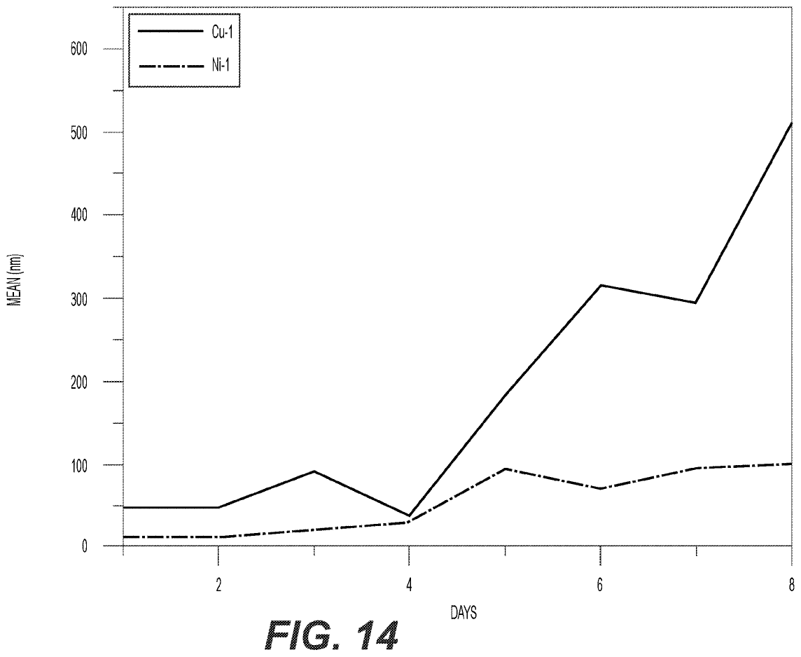

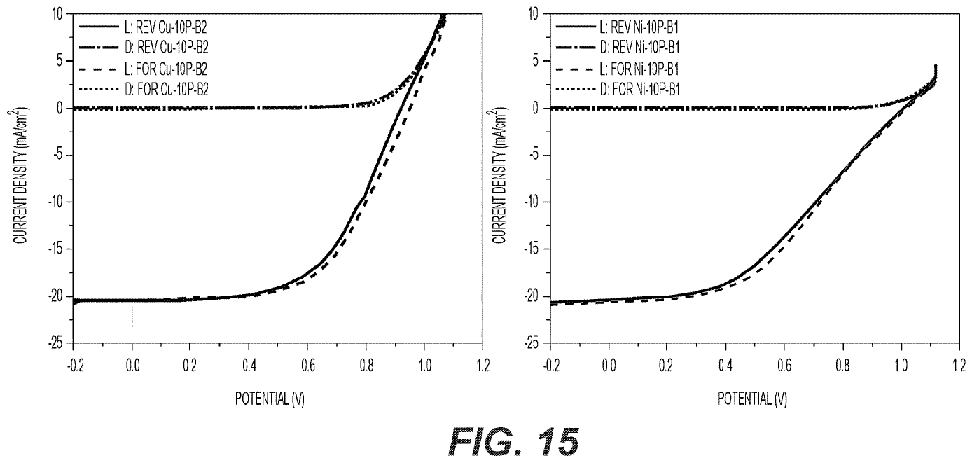

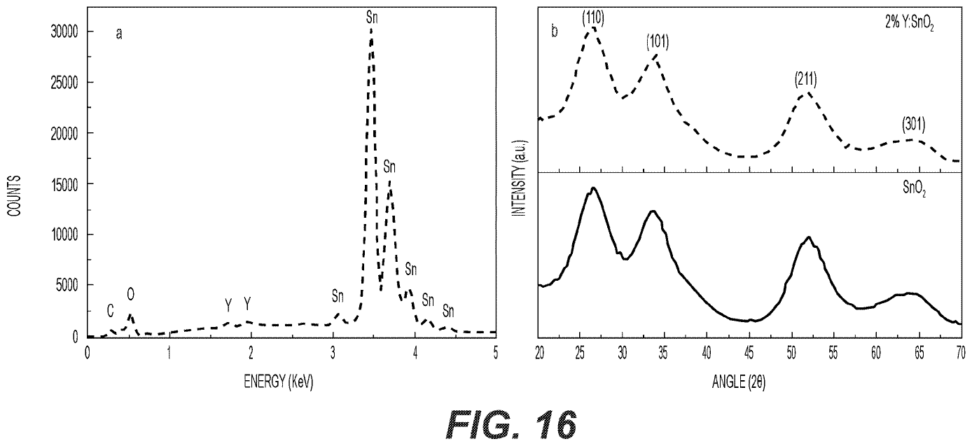

Doped and undoped nanoparticles where suspended in a 2:1 H₂O: Isopropyl alcohol solution by brief sonication and then filtered by centrifugation for 2 hr followed by filtering through a 0.2 μm nylon filter. The resulting suspensions were found to be stable up to 3 days by dynamic light scattering (FIG. 14). Using the fresh ink films deposited by roll to roll coating and intense pulsed light (IPL) annealing have resulted in peak devices of 8.85% NiO and 11.15% Ni_{0.94}Cu_{0.06}Oₓ for 0.25 cm² devices (Table C₁, FIG. 15). Complete devices where constructed using arcitechure of PET/ITO/NiOₓ/MAPbI₃/C₆₀/BCP/Ag. The perovskite film was deposited by blade coating using a 2-methoxyethanol: ACN ink and annealed using IPL.

TABLE C1
Cell Performance parameters and IPL conditions

| Sample | PCE (%) | J_{sc} (mA/cm²) | V_{oc} (V) | FF (%) |
|---|---|---|---|---|
| NiOₓ | 8.85 | 20.49 | 1.01 | 42.5 |
| Average NiOₓ | 8.06 | 20.29 | 0.99 | 39.8 |
| Ni_{0.94}Cu_{.06}Oₓ | 11.16 | 20.37 | 0.95 | 57.6 |
| Average Ni_{0.94}Cu_{.06}Oₓ | 9.86 | 19.82 | 0.90 | 54.7 |

| | Energy | Voltage | Duration | Delay | |
|---|---|---|---|---|---|
| IPL Parameters | (kJ) | (V) | (μs) | (ms) | Pulses |
| NiOₓ | 1.22 | 1940 | 1000 | 200 | 5 |
| MAPbI₃ | 0.37 | 1500 | 600 | 1000 | 10 |

### Example Set D—Yttrium Doped SnO₂ as an Efficient Blocking Layer for Inverted Flexible Perovskite Solar Cells (f-PSCs)

In this example, we investigated the direct deposition of tin (IV) oxide as an electron transport layer on the top of perovskite for the high-performance f-PSCs. We synthesized SnO₂ nanoparticles using the sol-gel method and functionalized them with acetate through ligand exchange allowing their dispersion in anhydrous ethanol. Additionally, we investigated in situ yttrium doping of SnO₂ during synthesis to enhance the performance of SnO₂ as an ETL. Nonaqueous dispersions of pristine and yttrium doped SnO₂ were directly deposited on the perovskite by blade coating followed by air knife treatment. There was no detectable damage to the underlying perovskite layer as evidenced by x-ray diffraction and scanning electron microscopy. Photoluminescence spectroscopy and device performance statistics confirm more electron extraction by yttrium doped SnO₂ as compared to pristine SnO₂. After, yttrium doping, the champion power conversion efficiency was increased above 18% from 14.40%, which is unprecedented for an inverted device in flexible ITO-PET substrate employing SnO₂ as an ETL. This example indicates scalable deposition of fully solution-processed metal oxide charge transfer layers directly on the perovskite should achieve highly efficient large-area flexible perovskite solar cells.

The perovskite solar cells (PSCs) device architecture can sometimes include a perovskite thin layer sandwiched between two charge transport layers and can be categorized as n-i-p or p-i-n, where n represents an electron transport layer (ETL) and p represents a hole transport layer (HTL). The ETL can play a role in PSCs including extraction and transportation of photogenerated electrons and preventing electron-hole recombination as a hole blocking layer. Therefore, ETL materials sometimes have a suitable band gap and proper energy alignment with the perovskite, along with high electron mobility and conductivity.

In this example, we synthesized Yttrium doped SnO₂ nanoparticles (Y:SnO₂) by sol-gel method, in part, to improve the electronic properties of the low temperature processed SnO₂. The Y:SnO₂ nanoparticles were functionalized with acetic acid to obtain acetate functionalized Y:SnO₂ (Y:SnO₂-A). The functionalization of Y:SnO₂ with acetate enables the formation of a stable colloidal dispersion of Y: SnO₂-A in anhydrous ethanol, which was directly deposited on the perovskite film by blade coating. The Y doping modifies the electronic properties of the ETL leading to an efficient extraction and transportation of the charge from underneath perovskite layer. As compared to pristine SnO₂, the champion power conversion efficiency (PCE) of the Y:SnO₂ device on the flexible PET substrate has increased from 14.40% to 18.2%. The work includes an analysis of the Y doping, thin film, and device characterization. This example shows that the scale-up of PSCs using inexpensive inorganic ETLs by high-throughput processes are possible.

### Result and Discussion

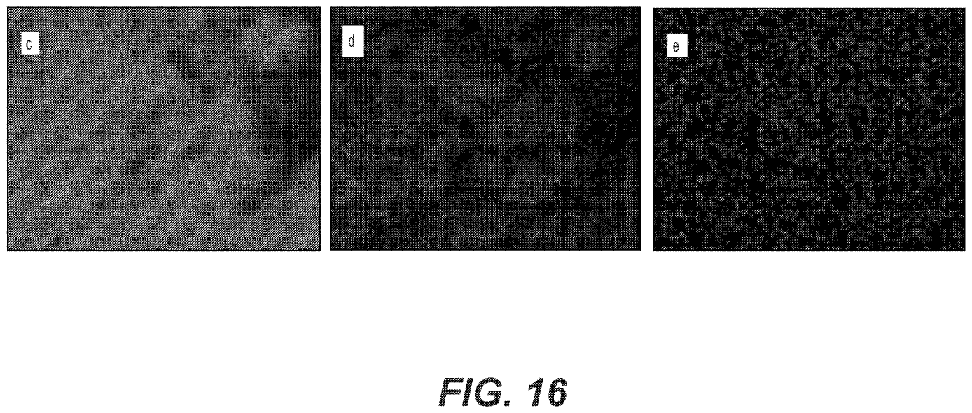

Pristine tin (IV) oxide (SnO₂) and yttrium doped tin (IV) oxide (Y:SnO₂) nanoparticles were synthesized using a solgel process as previously described (Chapagain et al. (2021) “Direct Deposition of Nonaqueous SnO₂ Dispersion by Blade Coating on Perovskites for the Scalable Fabrication of p-i-n Perovskite Solar Cells” ACS Appl. Energy Mater., Vol. 4, No. 10, pp. 10477-10483); however, yttrium doping was accomplished in situ by adding yttrium chloride to the to the precursor of SnO₂ (that is, anhydrous SnCl₄) during the synthesis process. Energy Dispersive X-ray Spectrometry (EDS) spectra of Y:SnO₂ reveal the presence of a Y in SnO₂ along with Sn and O (FIG. 16a). The elemental mapping of bulk Y:SnO₂ shows the uniform distribution of Yttrium in the matrix of the Y:SnO₂ (FIGS. 16c, 16d, and 16e). The crystal structure of the SnO₂ and Y:SnO₂ nanoparticles were analyzed employing powder X-ray diffraction (PXRD) (FIG. 16b).

The XRD peaks present at 26.4, 33.75, 51.86, and 64.37° are assigned to the (110), (101), (211), and (301) planes of the tetragonal rutile crystal structure of SnO₂ and Y:SnO₂. The XRD diffraction patterns of Y:SnO₂ do not show any extra peak of impurities which implies that either the amount of yttrium is not enough to change crystal structure or to exist as a separate phase.

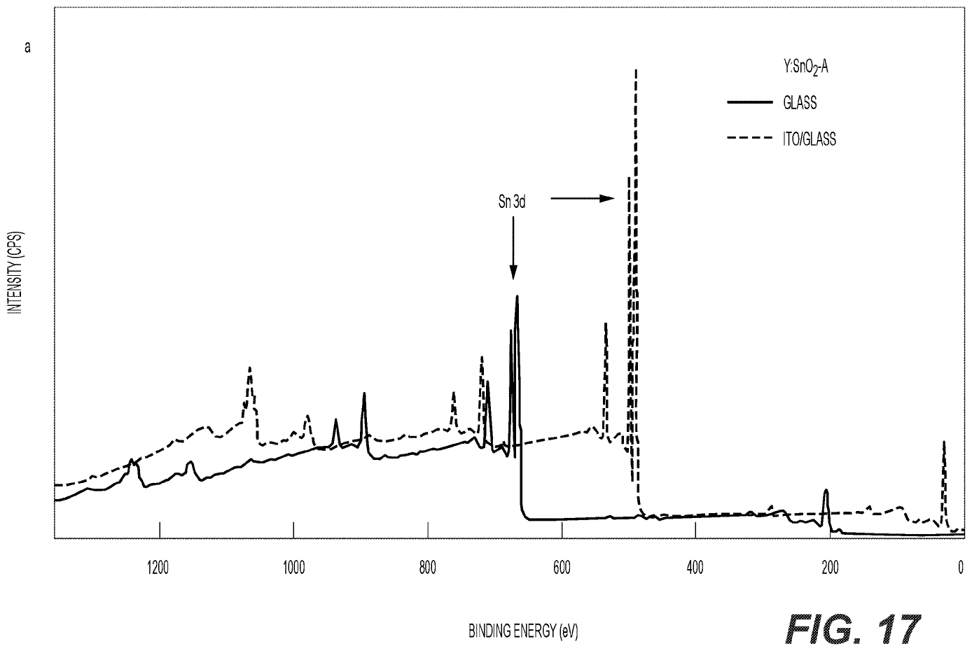

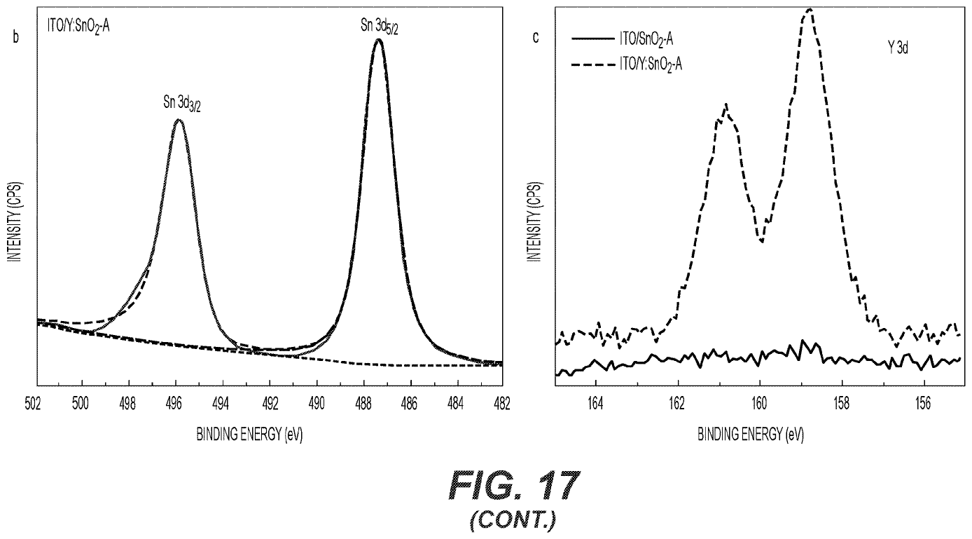

The elemental composition of the SnO₂ and Y:SnO₂ thin films were evaluated by X-ray photoelectron spectroscopy (XPS). Survey spectrum of Y:SnO₂ indicates the presence of C1s, O1s, and Sn 3d peaks along with other associated peaks (FIG. 17a). High-resolution core level spectra of Sn 3d contain doublet peaks at 487.4 eV and 495.8 eV corresponding to Sn 3d_{5/2} and Sn 3d_{3/2} (FIG. 17b). The doublet separation of Sn 3d_{5/2} and Sn 3d_{3/2} is 8.4 eV which corresponds to Sn⁴⁺ of SnO₂. Here, the curves in FIG. 17b represent the unfitted Sn 3d curves (solid line), curves after fitting (medium dashed line), the fitted curve for Sn 3d_{5/2} (long dashed line), and the fitted curve of Sn 3d_{3/2} (short dashed line). There is no significant difference in the line shape of Sn 3d_{5/2} of the SnO₂ and Y:SnO₂ thin film deposited on the ITO substrate (data not shown). FIG. 17c shows the presence of yttrium 3d peaks in Y:SnO₂ at B.E. 158.8 eV, however the yttrium 3d peak is absent in SnO₂. The results of EDS and XPS demonstrate the successful doping of SnO₂ with yttrium.

The deposition of SnO₂ and Y:SnO₂ nanoparticles directly on perovskite thin films can be accomplished by dispersion of the nanoparticles into perovskite compatible organic solvents. In Example A above, we functionalized SnO₂ with an acetate ligand to produce functionalized SnO₂ (SnO₂-A) which is dispersible in anhydrous ethanol. Here, we adopted the same strategy for functionalization of the Y:SnO₂ nanoparticles with an acetate yielding Y:SnO₂-A. The functionalization of Y:SnO₂ with acetate converts white amorphous tin oxide powder to a clear and colorless solution of functionalized tin oxide (Y:SnO₂-A). The X-ray diffraction (XRD) patterns of Y:SnO₂ before and after functionalization (data not shown) have similar peaks at 26.4, 33.75, 51.86, and 64.37° that are assigned to the (110), (101), (211), and (301) planes of the tetragonal rutile crystal structure of Y:SnO₂. XRD analysis shows that there is no change in the crystal structure of Y:SnO₂ after functionalization. The FTIR spectrum of SnO₂ before functionalization shows a broad band at 3300 cm⁻¹ and a sharp band at 1640 cm⁻¹ associated with OH stretching and bending of adsorbed water at the surface of Y:SnO₂. The OH stretching band is reduced in the FTIR spectrum of Y:SnO₂-A, which indicates that the hydroxyl groups on the surface of Y:SnO₂ have been replaced by acetate ligands; the coordination of acetate in Y:SnO₂-A is confirmed by the presence of bands at 1715 and 1380 cm⁻¹ associated with CO stretching and scissoring vibrations of the acetate ligand. Additionally, FT-IR spectra of Y:SnO₂ and Y:SnO₂-A show a common feature at 650 cm⁻¹ which is associated with Sn—O stretching. Hence, the functionalization processes of SnO₂ and Y:SnO₂ are purely ligand exchange processes as evident by XRD and FT-IR analysis.

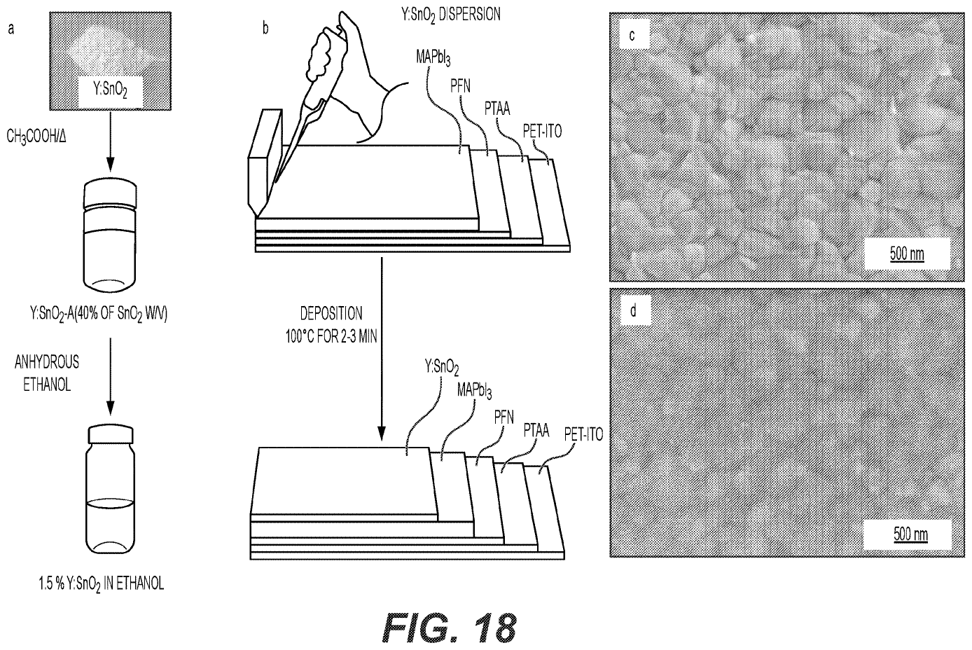

The overall scheme of the functionalization of Y:SnO₂ nanoparticles with acetate to obtain Y:SnO₂-A and ink formulation from Y:SnO₂ in anhydrous ethanol is presented in FIG. 18a. In contrast to Y:SnO₂, the Y:SnO₂-A nanoparticles are readily dispersed in protic organic solvents such as ethanol, isopropanol, and butanol. Without being bound by theory, the enhanced dispersibility of the Y:SnO₂-A nanoparticles in protic organic solvents could be attributed to the formation of a hydrogen-bonding network between the surface-bonded acetate, excess acetic acid, and alcohol.

The dispersion of Y:SnO₂-A nanoparticles can be deposited directly on the top of the perovskite layer via blade coating. After deposition, excess solvent can be removed quickly using a dry air knife. Here, annealing for 2 to 3 minutes at 100 °C ensures that the solvent is completely removed. See FIG. 18b.

FIGS. 18c and 18d are top surface SEM images of perovskite before and after Y:SnO₂-A deposition reveal a continuous and uniform layer of SnO₂. Additionally, there is no observed formation of lead iodide peaks, indicating that the perovskite has not been damaged during deposition.

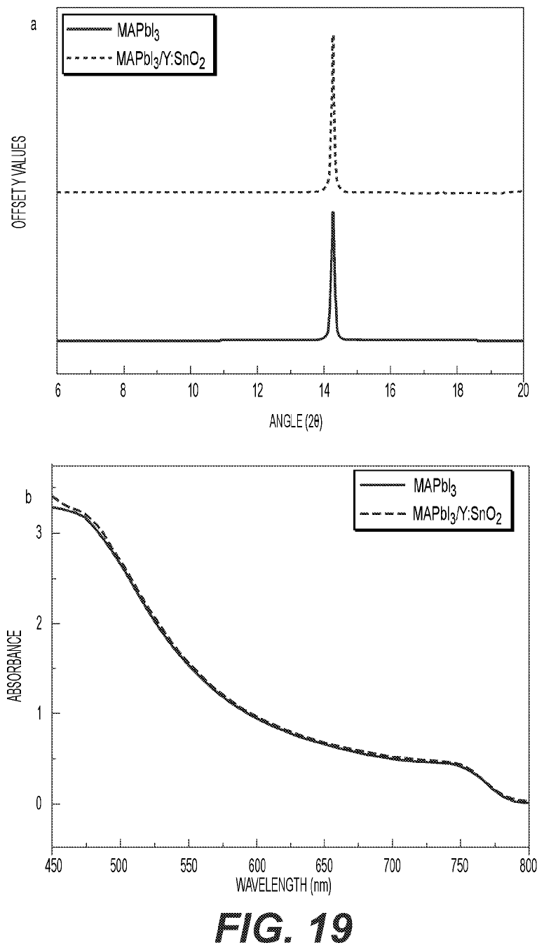

The XRD patterns of the perovskite before and after deposition of Y:SnO₂-A dispersion in anhydrous ethanol on the perovskite (FIG. 19a) further demonstrate that the deposition does not affect the perovskite. The XRD pattern of the perovskite before deposition of Y:SnO₂-A shows a single prominent peak at 14.1° as expected for CH₃NH₃PbI₃. The XRD pattern is unchanged after deposition of Y:SnO₂-A, indicating that the perovskite layer remains intact. No additional peak was observed at 12.7°; this indicates that moisture-assisted degradation resulting in PbI₂ formation did not occur. FIG. 19b shows the UV-Vis absorption spectra of the perovskite before and after Y:SnO₂-A deposition. The UV-Vis absorption spectra of perovskite before and after the deposition of Y:SnO₂-A on the perovskite are comparable and there is no significant change in optical absorption of the perovskite film. Additionally, there is no change in the band edge of the absorption spectra. The results of the UV-Vis analysis indicates that there is no effect of Y:SnO₂-A on the perovskite crystallinity and grain size.

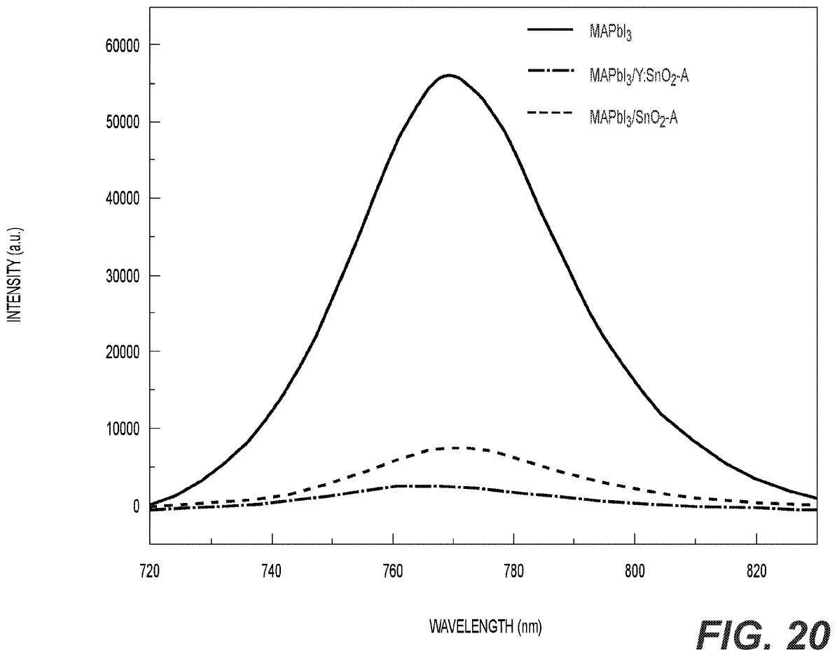

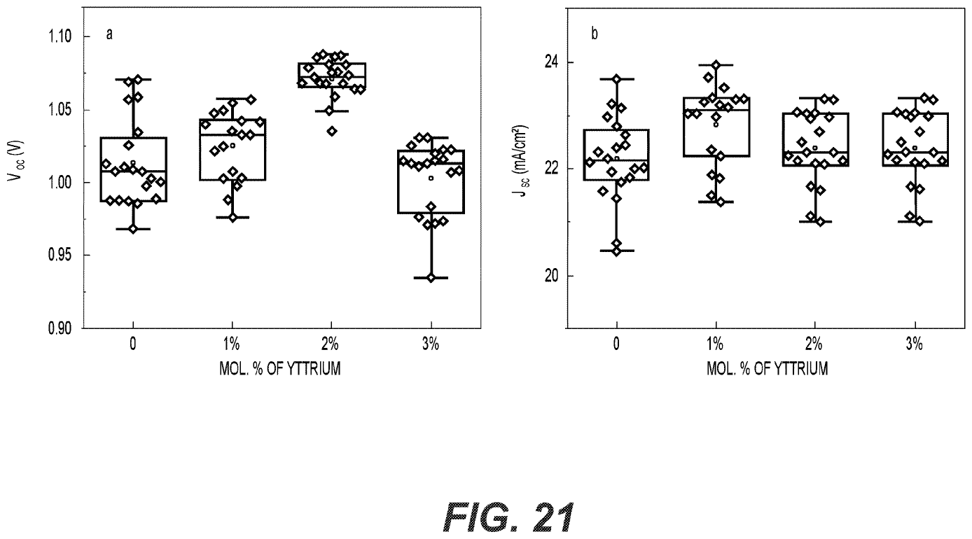

Steady-state photoluminescence (PL) measurements were carried out to understand charge carrier dynamics between the perovskite active layer and SnO₂-A and Y:SnO₂-A (FIG. 20). The perovskite film on PET substrate exhibited the highest PL intensity whereas the perovskite films with SnO₂-A and Y:SnO₂-A show significant PL quenching. It is observed that Y:SnO₂-A ETL shows a higher PL quenching as compared to pristine SnO₂-A, which indicates that the charge transfer is more efficient in the perovskite/Y:SnO₂-A interface than that of the perovskite/SnO₂-A interface.

To analyze the effect of Yttrium concentration in Y:SnO₂-A on the photovoltaic performance of the PSCs, a series of planar PSCs were fabricated on a flexible PET/ITO-based substrate (f-PSCs) employing diluted SnO₂-A and Y:SnO₂-A as ETLs. The overall device structures were ITO/PTAA/PFN/CH₃NH₃PbI₃/SnO₂-A/BCP/Ag and ITO/PTAA/PFN/CH₃NH₃PbI₃/Y:SnO₂-A/BCP/Ag, where a polytriarylamine (PTAA) is used as a hole transport layer (HTL) and a poly [(9,9-bis(3′-(N, N-dimethylamino) propyl)-2,7-fluorene)-alt-2,7-(9,9-dioctylfluorene)](PFN) as an interfacial layer. Here, PTAA, PFN, perovskite, and SnO₂ layers were deposited by one-step blade coating methods whereas BCP and silver were deposited by thermal evaporation. Those fabricated f-PSCs were measured under AM 1.5 simulated sunlight. Before measurement, the solar simulator was calibrated using NREL certified silicon reference photodiode using a KG5 filter.

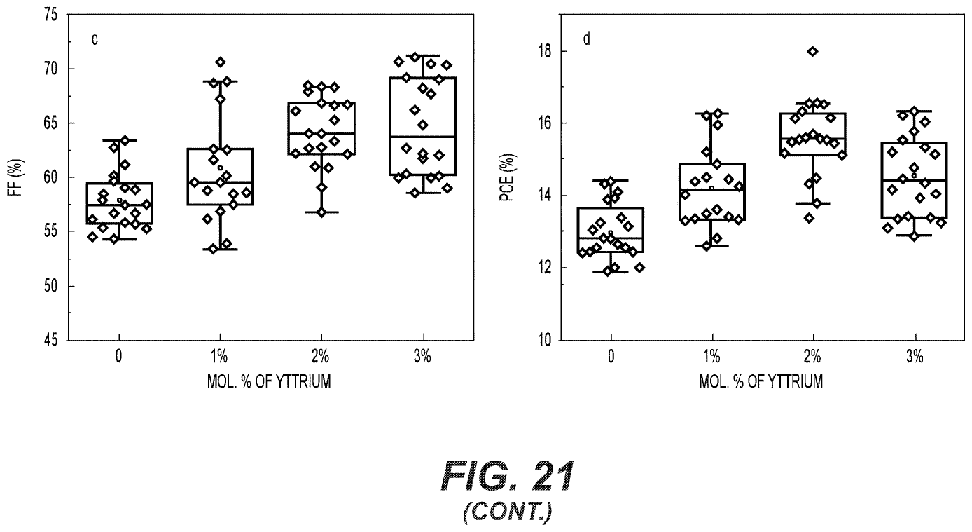

Device performance statistics of the f-PSCs vs doping concentrations of yttrium are presented in FIG. 21. The PCEs increased with an increase in yttrium concentration with an optimum performance being achieved with 2 mole % of yttrium in Y:SnO₂. The increase in PCE is attributed to an increase in open-circuit voltage (V_{OC}) and fill factor (FF). The increase in V_{oc} indicates an enhancement in conductivity after yttrium doping. The photovoltaic performance statistics of the f-PSCs with SnO₂ and Y:SnO₂ ETLs are summarized in Table D1.

TABLE D1
Summary of the average photovoltaic performance statistics
of the f-PSCs with 0, 1, 2, and 3 mol % of Yttrium in
SnO₂ ETL with an active area of 0.1 cm²

| Mol. % of Y | Voc (V) | Jsc (mA/cm²) | FF (%) | PCE (%) |
|---|---|---|---|---|
| 0 | 1.01 ± 0.03 | 22.18 ± 0.80 | 57.83 ± 2.5 | 13.0 ± 0.77 |
| 1 | 1.02 ± 0.02 | 22.83 ± 0.77 | 60.83 ± 5.0 | 14.22 ± 1.11 |
| 2 | 1.07 ± 0.01 | 22.62 ± 0.68 | 64.17 ± 3.2 | 15.56 ± 1.05 |
| 3 | 1.00 ± 0.02 | 22.38 ± 0.67 | 64.71 ± 4.5 | 14.52 ± 1.12 |

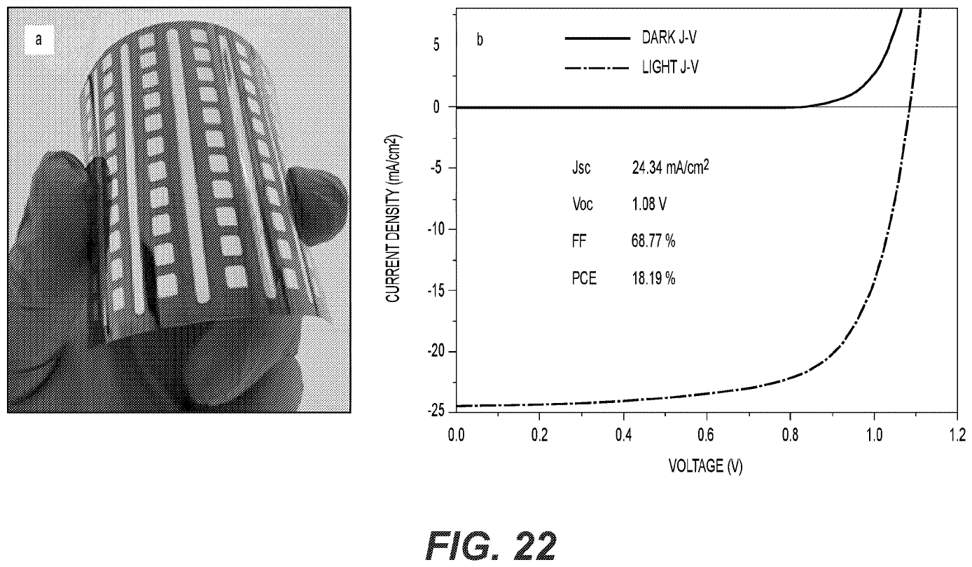

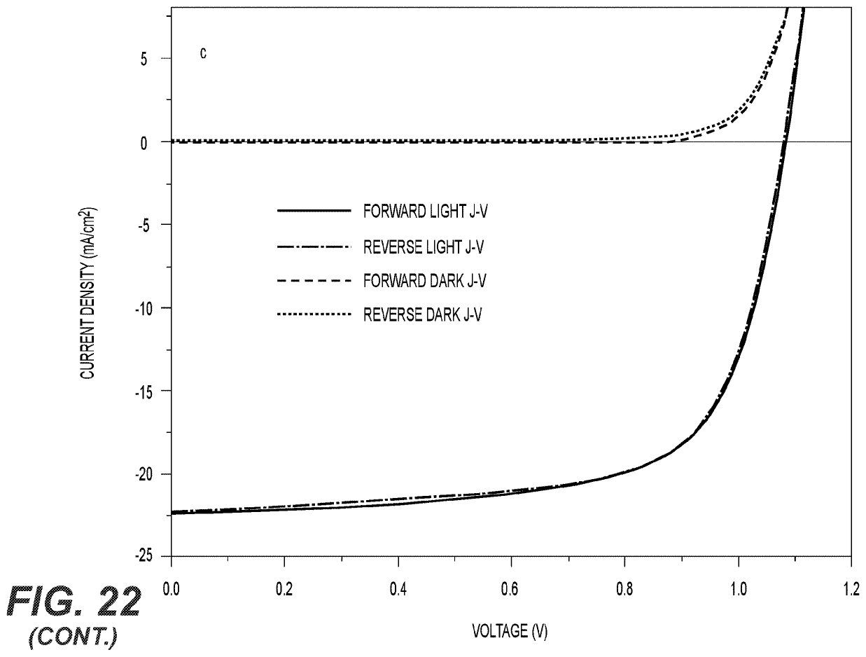

An image of blade-coated f-PSCs are presented in FIG. 22a. It is noteworthy, the PCE of the champion f-PSC with 2% Y:SnO₂-A is ~4% higher than the PCE of the champion f-PSC with pristing SnO₂-A. The device with 2% Y:SnO₂-A exhibited a champion PCE of 18.19% with a J_{sc} of 24.34 mA/cm², a V_{oc} of 1.08 V, and an FF of 68.77% (FIG. 22b). FIG. 22c highlights minimal hysteresis between forward and reverse scan of the f-PSCs with 2% Y:SnO₂ as an ETL.

### Conclusion

We synthesized yttrium doped tin (IV) oxide (Y:SnO₂) via in situ addition of yttrium chloride to the solgel synthesis of SnO₂. Both pristine SnO₂ and Y:SnO₂ nanoparticles were functionalized with acetate and diluted with anhydrous ethanol yielding a nonaqueous dispersion of SnO₂-A and Y:SnO₂-A. The non-aqueous dispersion of SnO₂-A and Y:SnO₂-A did not induce any observable damage to the perovskite during deposition by blade coating as evident by XRD and UV-Vis. The PL analysis shows Y:SnO₂-A has better charge carrier dynamics than that of the pristine SnO₂-A. We successfully fabricated inverted f-PSCs on the PET substrate by direct deposition of fully solution-processed SnO₂-A and Y:SnO₂-A on the perovskite by a scalable blade coating method. The f-PSCS with Y:SnO₂-A as an ETL exhibit improved performance as compared to pristine SnO₂-A. The optimum yttrium concentration was found to be 2 mol % yielding a 20% improvement in average performance, with increases to both the V_{oc} and FF. The low temperature synthesized Y:SnO₂-A is a promising ETL and blocking layer and is fully solution-processed. This material possesses multiple cost, scalability, and manufacturing advantages over traditional organic ETLs that could improve the competitiveness of commercial perovskite solar modules.

### Experimental Section

### Synthesis of SnO₂ and Y:SnO₂

Both SnO₂ and Y:SnO₂ nanoparticles were synthesized by a sol-gel method by neutralizing 1M aqueous tin (IV) chloride solution with 5M sodium hydroxide solution. The SnO₂ and Y:SnO₂ nanoparticles were synthesized similarly, but the Yttrium doping was accomplished in situ by adding Yttrium precursor to the precursor of tin oxide during the synthesis process. 1M aqueous tin (IV) chloride solution was prepared by dropwise addition of anhydrous tin (IV) chloride to deionized (DI) water. To the continuously stirred aqueous tin (IV) chloride solution, a freshly prepared aqueous solution of 5M sodium hydroxide was added dropwise until the pH reached 6.5. The resulting white precipitate of SnO₂ was aged for 12 hrs, collected by centrifugation, washed repeatedly by dispersion in DI water, and in the mixture of 1:1 DI water and ethanol by centrifugation until the aqueous layer was free from chloride. The washed SnO₂ nanoparticles were dried at room temperature. To prepare 1, 2, and 3 mol. % yttrium doped SnO₂, a calculated amount of yttrium (III) chloride hydrate was added to the aqueous 1M tin (IV) chloride solution respectively.

### Functionalization of SnO₂ and Y:SnO₂ with Acetate

Both SnO₂ and Y:SnO₂ were functionalized with an acetate based on Examples discussed herein. Here, SnO₂ or Y:SnO₂ was mixed with glacial acetic acid in a 1:1 mass by volume ratio. Then, the mixture of SnO₂ and glacial acetic acid or Y:SnO₂ and acetic acid were heated at reflux for 1 hr in a closed container fitted with a condenser and thermometer. The mixture initially forms milky white colloidal dispersion which becomes transparent upon the completion of functionalization. The presence of undissolved SnO₂ nanoparticles leaves milky white coloration which can be removed via centrifugation. The percentage of SnO₂ in the clear solution of functionalized SnO₂ was determined from TGA analysis and the functionalized SnO₂ nanoparticles were characterized by XRD, FT-IR, and UV-Vis methods. For XRD and FTIR analysis, any solvents present in the functionalized tin (IV) oxide nanoparticles were evaporated and the solid product was dried in a vacuum oven at 100 °C for 2 hr before analysis. The functionalized SnO₂ and Y:SnO₂ were diluted with anhydrous ethanol to get 1.5% (m/v) of SnO₂ which is suitable for blade coating directly on the perovskite.

### Device Fabrication

ITO-PET substrate was cut into 6×8 in. pieces, and they were blown with an air gun and wiped using IPA. Those cleaned PET substrates were treated with UV-Ozone for 15 minutes immediately before the sequential deposition of PTAA, PFN, CH₃NH₃PbI₃, and SnO₂ or Y:SnO₂ dispersion by blade coating inside a dry box. A PTAA solution was prepared by dissolving 8 mg of PTAA in 1 mL of toluene. A 60 μL of the PTAA solution was used for blade coating with a blade gap of 100 μm at a coating speed of 10 mm/s, followed by heating at 100 °C for 10 min and then cooled down to room temperature. Next, 60 μL of a 0.4 mg/mL PFN solution in methanol was blade-coated on the PTAA layer at a coating speed of 10 mm/s with a blade gap of 100 μm. The perovskite precursor solution was prepared by dissolving methylammonium iodide and lead iodide in a mixture of DMF/DMSO/NMP with a volume ratio of 0.91:0.07:0.02 to get a 1.2 M solution. 70 μL of the perovskite precursor solution was deposited by blade coating with a blade gap of 150 μm and at a coating speed of 10 mm/s. Immediately after the deposition of perovskite precursor solution, the wet film was predried using an N₂ air knife, followed by hotplate annealing at 140 °C for 2 min. Finally, 60 μL of the SnO₂-A or Y:SnO₂-A dispersion in anhydrous ethanol was deposited on the perovskite with a blade gap height of 100 μm and at a coating speed of 10 mm/s, followed by annealing at 100 °C for 2 to 3 min. The fabrication of PSCs having a device architecture of PET-ITO/PTAA/PFN/CH₃NH₃PbI₃/BCP/SnO₂-A/Ag and PET-ITO/PTAA/PFN/CH₃NH₃PbI₃/BCP/Y:SnO₂-A/Ag and an active area of 0.1 cm² were completed by depositing 5 nm of BCP and 100 nm of silver employing thermal evaporation.

### Physical Methods

X-ray photoelectron spectroscopy (XPS): VG Scientific MultiLab 3000
Energy Dispersive X-ray Spectrometry (EDS) spectra: TESCAN Vega3 SEM with EDS Detector
Powder XRD patterns were obtained using a Bruker D8 Discover X-ray diffractometer.
Infrared spectra were collected using a Thermo Nicolet Avatar 360 FT-IR spectrometer with Smart iTR.
UV-Vis analyses were carried out on a Agilent 8453 UV-Vis spectrometer.

The top section SEM images were obtained using a JEOL 7000 field-emission scanning electron microscope. PL analysis was carried out using a Renishaw in Via Raman microscope with a CCD detector and a 632 nm He—Ne laser source. The current density-voltage (J-V) characteristics of devices were measured using a Class AAA solar simulator having a xenon arc lamp under 1 sun condition (AM1.5G, 100 mW/cm²). Prior to the device measurements, the solar simulator was calibrated using an NREL-certified Si reference cell. Devices were tested from 1.2 to 0 V at a scan rate of 100 mV/s with a step size of 10 mV

### Example Set E—Yttrium Doping on SnO₂

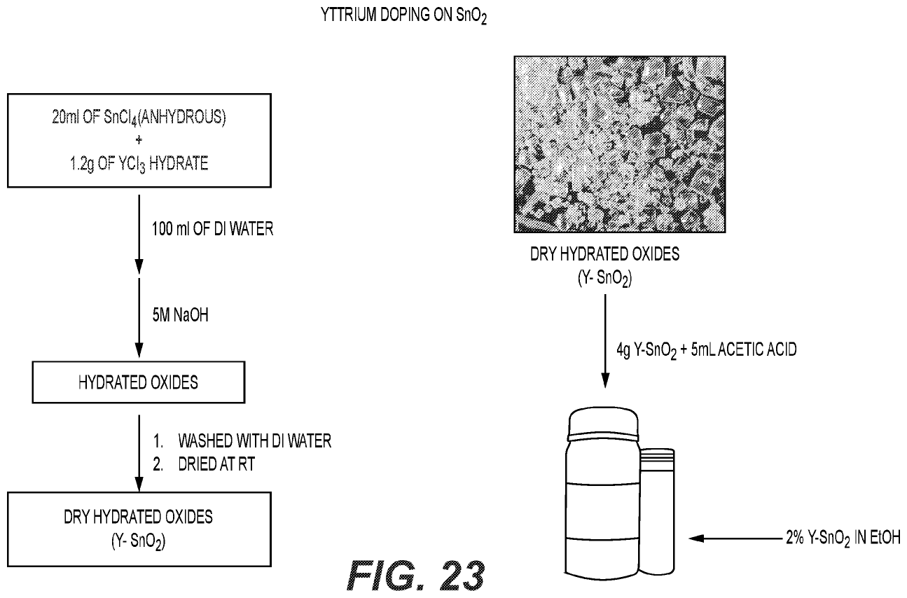

A series of yttrium doped tin (IV) oxide (Y:SnO₂) nanoparticles (NPs) were synthesized using a slight modification of the solgel process that we recently reported for the synthesis of pristine tin(IV) oxide (SnO₂) particles (Chapagain et al. (2021) “Direct Deposition of Nonaqueous SnO₂ Dispersion by Blade Coating on Perovskites for the Scalable Fabrication of p-i-n Perovskite Solar Cells” ACS Appl. Energy Mater., Vol. 4, No. 10, pp. 10477-10483). For the synthesis Y:SnO₂ nanoparticles, yttrium chloride was added to aqueous solution of anhydrous SnCl₄ during the synthesis process in the appropriate ratios to get 1% Y: SnO₂, 2% Y:SnO₂, and 3% Y:SnO₂ (FIG. 23).

To enhance dispersibility in perovskite compatible organic solvents, the Y:SnO₂ NPs were functionalized with acetate to yield Y:SnO₂-A. Acetate functionalization converts the amorphous, white powder of Y:SnO₂ to a clear and colorless solution of functionalized tin oxide (Y:SnO₂-A) in glacial acetic acid. Here, as shown in FIG. 23, Y:SnO₂ was mixed with glacial acetic acid in a 1:1.25 mass by volume ratio. However, the ratio of Y:SnO₂ and acetic acid depends on the purpose of applications. Then, the mixture of Y:SnO₂ and acetic acid were heated at reflux for 1 hr in a closed container fitted with a condenser and thermometer. The mixture initially forms milky white colloidal dispersion which becomes transparent upon the completion of functionalization. The presence of undissolved Y:SnO₂ nanoparticles leaves milky white coloration which can be removed via centrifugation. The percentage of Y:SnO₂ in the clear solution of functionalized Y:SnO₂ (Y:SnO₂) was determined from TGA analysis and the Y:SnO₂-A nanoparticles were characterized by XRD, FT-IR, and UV-Vis methods. For XRD and FTIR analysis, any solvents present in the functionalized tin (IV) oxide nanoparticles were evaporated and the solid product was dried in a vacuum oven at 100 °C for 2 hr before analysis. The Y:SnO₂-A was diluted with anhydrous ethanol to get 1.5% (m/v) of Y:SnO₂ which is suitable for blade coating directly on the perovskite.

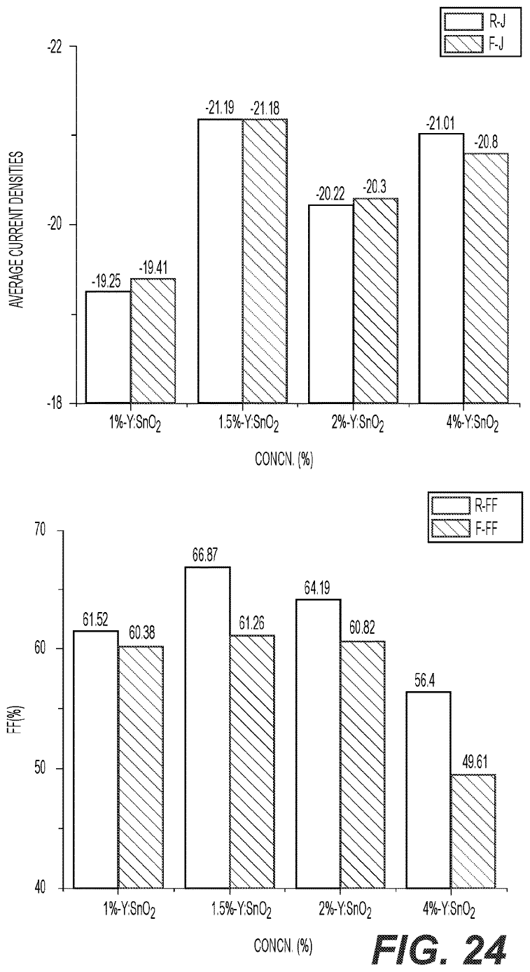

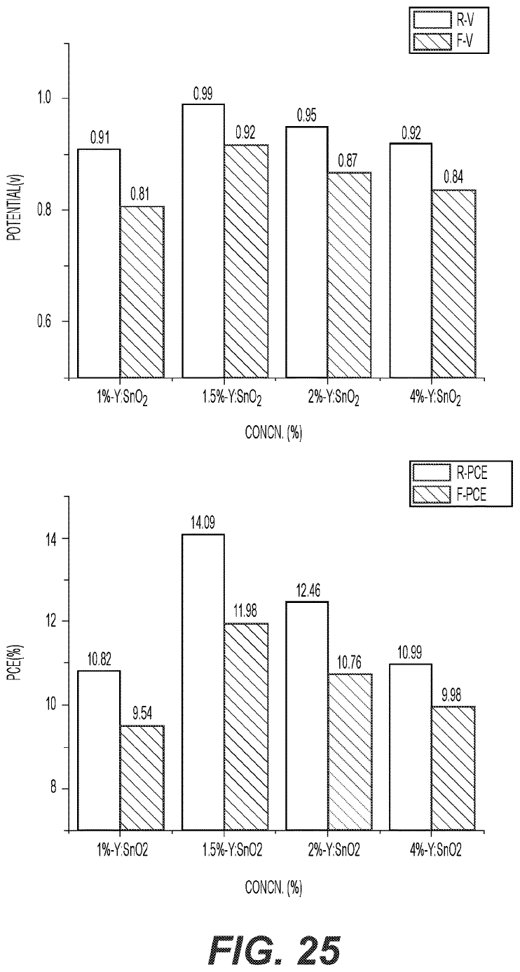

The photovoltaic performance of the perovskite solar cells vs concentration Y:SnO₂ is presented in FIG. 24 and FIG. 25, for forward (F) and reverse (R) measurements.

### Example Set F

Perovskite ink was prepared by dissolving PbI₂ and MAI in dimethyl sulfoxide (DMSO, 7%), N-methyl-2-pyrrolidone (NMP, 2%), and dimethylformamide (DMF, 91%) to make a 1.2M solution by gentle stirring. The perovskite was deposited on PET by blade coating with a blade gap of 100 μm at a speed of 10 mm sec⁻¹ at room temperature. After perovskite deposition, the films were dried with a N₂ knife at a pressure of 40 psi prior to annealing at 140 °C for 2 minutes. The NiOₓ inks were prepared by sonication of NiOₓ particles (20 mg) in 200 μL of a 3:1 (v/v) Et₃N/EtOH mixture for 60 minutes at 65 °C in a closed vial. The resulting suspension was diluted with 700 μL CB and 100 μL EtOH to make a 20 mg/mL NiOₓ solution. After dilution, the suspensions were sonicated with heating at 65 °C. The hot ink suspensions were filtered through 0.2 μm PTFE prior to blade coating. 40 μL inch-2 of the NiOₓ inks were deposited on the perovskite by blade coating using an optimized blade gap of 225 μm at a speed of 5 mm sec-1.

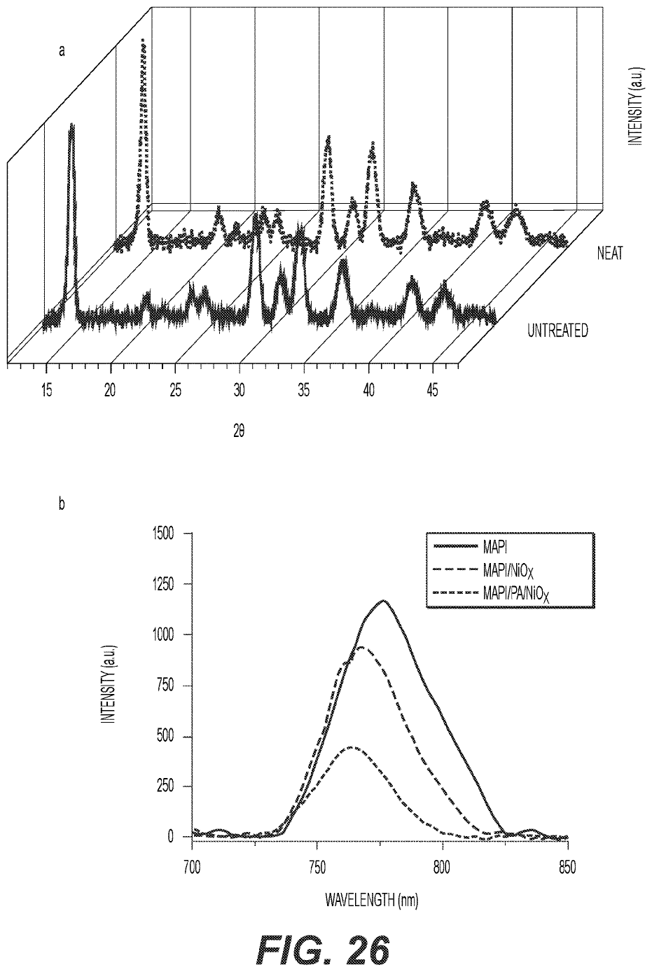

Results with neat NiOₓ (no added PA) confirm successful solution phase deposition on perovskite. The XRD pattern (FIG. 26a) of methylammonium lead iodide (MAPI) on ITO before and after deposition are nearly identical with a prominent MAPI peak at 14. 1 and no detectable PbI₂ degradation peak at 12.7. Photoluminescence (PL) studies (FIG. 26b) with NiOₓ and an imidazolium PA confirm the further benefits of including multi-functional passivating agents. The imidazolium was deposited on the perovskite surface by blade coating. The imidazolium was suspended at a concentration of 0.04 mg/mL solution in EtOH and was coated at 10 mm/sec with a blade height of 100 μm. Deposition of NiOₓ on MAPI decreases PL intensity associated with charge extraction. Addition of our multifunctional imidazolium PA with the NiOₓ improves the charge extraction. Functional p-i-n devices have been prepared using solution phase deposition of NiOₓ nanoparticles with efficiencies of 14.47% (0.25 cm²) and 9.60% (1.0 cm²). From the J-V curves, it is seen that series and shunt resistances are affecting device performance. Notably, the same solvent system was used for NiOₓ and SnO₂ deposition on MAPI with only the latter giving functional devices to date. There may be surface differences in these two cases that could be mediated by inclusion of an interfacial passivation layer.

The headings used in the disclosure are not meant to suggest that all disclosure relating to the heading is found within the section that starts with that heading. Disclosure for any subject may be found throughout the specification.

It is noted that terms like “preferably,” “commonly,” and “typically” are not used herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

As used in the disclosure, “a” or “an” means one or more than one, unless otherwise specified. As used in the claims, when used in conjunction with the word “comprising” the words “a” or “an” means one or more than one, unless otherwise specified. As used in the disclosure or claims, “another” means at least a second or more, unless otherwise specified. As used in the disclosure, the phrases “such as”, “for example”, and “e.g.” mean “for example, but not limited to” in that the list following the term (“such as”, “for example”, or “e.g.”) provides some examples but the list is not necessarily a fully inclusive list. The word “comprising” means that the items following the word “comprising” may include additional unrecited elements or steps; that is, “comprising” does not exclude additional unrecited steps or elements.

Unless otherwise indicated, all numbers expressing quantities of ingredients, properties such as reaction conditions, and so forth used in the specification and claims are to be understood as being modified in all instances by the term “about”. Accordingly, unless indicated to the contrary, the numerical parameters set forth in this specification and claims are approximations that can vary depending upon the desired properties sought to be obtained by the presently-disclosed subject matter.

As used herein, the term “about,” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

Detailed descriptions of one or more embodiments are provided herein. It is to be understood, however, that the present invention may be embodied in various forms. Therefore, specific details disclosed herein (even if designated as preferred or advantageous) are not to be interpreted as limiting, but rather are to be used as an illustrative basis for the claims and as a representative basis for teaching one skilled in the art to employ the present invention in any appropriate manner. Indeed, various modifications of the invention in addition to those described herein will become apparent to those skilled in the art from the foregoing description and the accompanying figures. Such modifications are intended to fall within the scope of the appended claims.

What is claimed is:

1. A method for preparing a Perovskite Solar Cell (PSC), the method comprising:
dissolving a functionalized material in a solvent, where the functionalized material is a material that is functionalized with one or more functionalizing compounds;
depositing a deposit composition on a perovskite layer, where the deposit composition comprises the dissolved functionalized material;
heating the deposit composition; and
optionally removing some or all of the one or more functionalizing compounds from the deposit composition.

2. The method of claim 1, wherein the material of the functionalized material comprises one or more of an organic material, a metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene.

3. The method of claim 1 or claim 2, wherein the material comprises one or more of a doping substance.

4. The method of any of the preceding claims, wherein the material comprises one or more doping substances and the one or more doping substances comprises Zr, Sb, Li, Mg, Y, Nb, Cu, or Mo.

5. The method of any of the preceding claims, wherein the material of the functionalized material comprises one or more of an organic material, a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene.

6. The method of any of the preceding claims, wherein the material of the functionalized material comprises one or more of an a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene.

7. The method of any of the preceding claims, wherein the material of the functionalized material comprises one or more of TiO₂, SnO₂, NiOₓ, CuO, ZnO, Zn₂SO₄, WO₃, In₂O₃, SrTiO₃, Nb₂O₅, BaSnO₃, Y:SnO₂, or Cu:NiOₓ.

8. The method of any of the preceding claims, wherein the material of the functionalized material comprises one or more of SnO₂, NiOₓ, Y:SnO₂, or Cu:NiOₓ.

9. The method of any of the preceding claims, wherein the one or more functionalizing compounds is one or more of:
(1) R₁ₐ—CO—OH (I),
or salts thereof, where R₁ₐ is substituted or unsubstituted alkyl;
(2) R₂ₐ—O—CS₂⁻M⁺₂ₐ (II),
where R₂ₐ is substituted or unsubstituted alkyl, and M⁺₂ₐ is a cation; 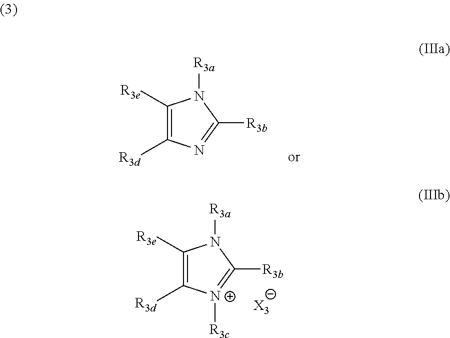
where X₃ is an anion; R₃ₐ, R_{3c}, R_{3d}, and R₃ₑ is the same or different and is H, substituted or unsubstituted alkyl, or substituted or unsubstituted aryl; R_{3b} is H, substituted or unsubstituted alkyl, substituted or unsubstituted aryl, substituted or unsubstituted Lewis base, quaternary nitrogen salts, carboxylates, xanthates, alkoxides, or thiolates; 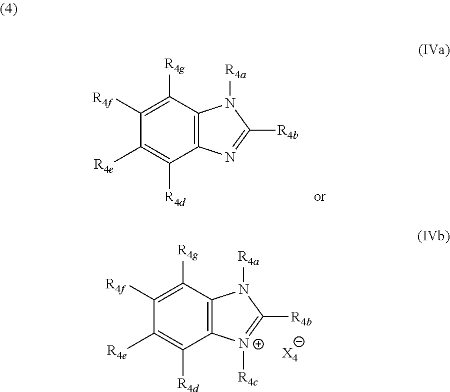
where X₄ is an anion; R₄ₐ, R_{4c}, R_{4d}, R₄ₑ, R_{4f}, and R_{4g} is the same or different and is H, substituted or unsubstituted alkyl, or substituted or unsubstituted aryl; R_{4b} is H, substituted or unsubstituted alkyl, substituted or unsubstituted aryl, substituted or unsubstituted Lewis base, quaternary nitrogen salts, carboxylates, xanthates, alkoxides, or thiolates; 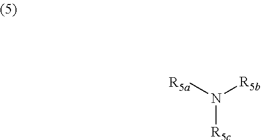
where R₅ₐ, R_{5b}, and R_{5c} is the same or different and is H, substituted or unsubstituted alkyl, or substituted or unsubstituted aryl; 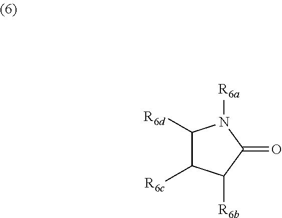
where R_{6b}, R_{6c}, and R_{6d} is the same or different and is H, substituted or unsubstituted alkyl, or substituted or unsubstituted aryl; R₆ₐ is H, substituted or unsubstituted alkyl, substituted or unsubstituted aryl,
where the R₆ₐ substituted alkyl is optionally substituted with one or more substituted or unsubstituted Lewis bases, quaternary nitrogen salts, carboxylates, xanthates, alkoxides, or thiolates,
where the R₆ₐ substituted aryl is optionally substituted with one or more substituted or unsubstituted Lewis bases, quaternary nitrogen salts, carboxylates, xanthates, alkoxides, or thiolates; or
(7) R₇ₐ—NH—CS₂⁻M⁺₇ₐ (VII),
where R₇ₐ is a substituted or unsubstituted alkyl and M⁺₂ₐ is a cation.

10. The method of any of the preceding claims, wherein R₁ₐ is a substituted or unsubstituted C₁-C₈alkyl, methyl, ethyl, propyl, or butyl.

11. The method of any of the preceding claims, wherein R₂ₐ is a substituted or unsubstituted alkyl C₁-C₃₆ alkyl, methyl, ethyl, propyl, butyl, dodecyl, or octadecyl; M⁺₂ₐ is Na⁺, K⁺, or Li⁺; or a combination thereof.

12. The method of any of the preceding claims, wherein X₃ is Cl⁻, Br⁻, I⁻, BF₄⁻, PF₆⁻, or CF₃SO₃⁻; R₃ₐ, R_{3c}, R_{3d}, and R₃ₑ is the same or different and is H, substituted or unsubstituted C₁-C₈ alkyl, or substituted or unsubstituted phenyl; R_{3b} is H, substituted or unsubstituted C₁-C₈ alkyl, substituted or unsubstituted phenyl, —C(O)H, —C(O)OH, —C(O)NHR_{3f}, —CH₂OR_{3f}, —CH₂NHR_{3f}, quaternary nitrogen salts, carboxylates, xanthates, alkoxides, or thiolates, R_{3f} is H, substituted or unsubstituted C₁-C₈ alkyl; or a combination thereof.

13. The method of any of the preceding claims, wherein X₄ is Cl⁻, Br⁻, I⁻, BF₄⁻, PF₆⁻, or CF₃SO₃⁻; R₄ₐ, R_{4c}, R_{4d}, R₄ₑ, R_{4f}, and R_{4g} is the same or different and is H, substituted or unsubstituted C₁-C₈ alkyl, or substituted or unsubstituted phenyl; R_{4b} is H, substituted or unsubstituted C₁-C₈ alkyl, substituted or unsubstituted phenyl, —C(O)H, —C(O)OH, —C(O)NHR₄ₕ, —CH₂OR₄ₕ, —CH₂NHR₄ₕ, quaternary nitrogen salts, carboxylates, xanthates, alkoxides, or thiolates, R₄ₕ is H, substituted or unsubstituted C₁-C₈ alkyl; or a combination thereof.

14. The method of any of the preceding claims, wherein R₅ₐ, R_{5b}, and R_{5c} is the same or different and is H, substituted or unsubstituted C₁-C₈ alkyl, or substituted or unsubstituted phenyl.

15. The method of any of the preceding claims, wherein R_{6b}, R_{6c}, and R_{6d} is the same or different and is H, substituted or unsubstituted C₁-C₈ alkyl, or substituted or unsubstituted phenyl; R₆ₐ is H, substituted or unsubstituted C₁-C₈ alkyl, substituted or unsubstituted phenyl, where the R₆ₐ substituted alkyl is optionally substituted with one or more —C(O)H, —C(O)OH, —C(O)NHR₆ₑ, —CH₂OR₆ₑ, —CH₂NHR₆ₑ, quaternary nitrogen salts, carboxylates, xanthates, alkoxides, or thiolates, where the R₆ₐ substituted aryl is optionally substituted with one or more —C(O)H, —C(O)OH, —C(O)NHR₆ₑ, —CH₂OR₆ₑ, —CH₂NHR₆ₑ, quaternary nitrogen salts, carboxylates, xanthates, alkoxides, or thiolates, R₆ₑ is H, substituted or unsubstituted C₁-C₈alkyl; or a combination thereof.

16. The method of any of the preceding claims, wherein R₇ₐ is a substituted or unsubstituted alkyl C₁-C₃₆ alkyl, methyl, ethyl, propyl, butyl, dodecyl, or octadecyl; M⁺₇ₐ is Na⁺, K⁺, or Li⁺; or a combination thereof.

17. The method of any of the preceding claims, wherein formula (IIIb) is

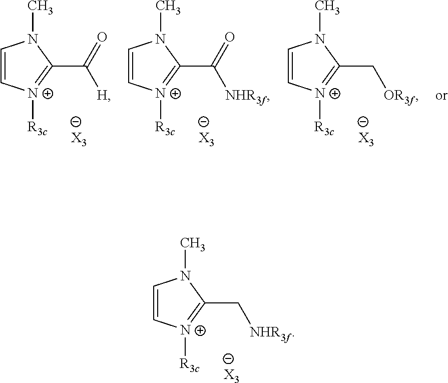

18. The method of any of the preceding claims, wherein formula (V) is selected from triarylamines (TAA), substituted TAA, triphenylamine, substituted triphenylamines, triethylamine and substituted triethylamines.

19. The method of any of the preceding claims, wherein the functionalized material comprises one or more of a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, Y:SnO₂, Cu:NiOₓ, C₆₀, C₇₀, PC₆₁BM, PC₇₁BM, or fullerene,
where each is independently functionalized with (i) one or more of formula (I) or salts thereof, where R₁ₐ is C₁-C₄ alkyl, (ii) one or more of formula (II), where R₂ₐ is C₁-C₂₇ alkyl and M⁺₂ₐ is Na⁺, K⁺, or Li⁺, (iii) triethylamine, or (iv) a combination thereof.

20. The method of any of the preceding claims, wherein the functionalized material comprises one or more of a metal oxide, a doped metal oxide, TiO₂, SnO₂, NiOₓ, CuO, ZnO, Zn₂SO₄, WO₃, In₂O₃, SrTiO₃, Nb₂O₅, BaSnO₃, C₆₀, C₇₀, PC₆₁BM, PC₇₁BM, or fullerene, where each is independently functionalized with one or more of formula (I) or salts thereof, where R₁ₐ is C₁-C₄ alky.

21. The method of any of the preceding claims, wherein the functionalized material comprises one or more of TiO₂, ZnO, Y:SnO₂, Cu:NiOₓ, NiOₓ, or SnO₂ where each is independently functionalized with acetate, propionate, triethylamine, Na C₁₈ alkyl xanthate, Na C₁₂ alkyl xanthate, or a combination thereof.

22. The method of any of the preceding claims, wherein the functionalized material comprises one or more of TiO₂, ZnO, NiOₓ, or SnO₂ where each is independently functionalized with one or both of acetate or propionate.

23. The method of any of the preceding claims, wherein the solvent comprises a protic solvent, an anhydrous protic solvent, anhydrous methanol, anhydrous ethanol, anhydrous isopropanol, anhydrous C₁₋₁₀ alcohol, THF, dimethyl ether, diethyl ether, an anhydrous ether, an ether, chlorobenzene (CB), or a combination thereof.

24. The method of any of the preceding claims, wherein the depositing step is performed by one or more of blade coating, spin coating, slot die, gravure, flexo, spray, or inkjet.

25. The method of any of the preceding claims, wherein the depositing step is performed by blade coating.

26. The method of any of the preceding claims, wherein the heating step comprises annealing or intense pulsed light (IPL).

27. The method of any of the preceding claims, wherein the heating step comprises heating at about 80 °C to about 120 °C for about 5 to about 20 minutes.

28. The method of any of the preceding claims, wherein the heating step removes some or all of the one or more functionalizing compounds.

29. The method of any of the preceding claims, wherein the removing step occurs.

30. The method of any of the preceding claims, wherein the removing step occurs by heat or by intense pulsed light (IPL).

31. The method of any of the preceding claims, wherein (i) the heating step removes some of the one or more functionalizing compounds and (ii) the removing step occurs, and further removes some of or all of the remainder of the one or more functionalizing compounds.

32. The method of any of the preceding claims, wherein the perovskite layer comprises one or more of CH₃NH₃PbX₃, CH₃NH₃PbI₃, H₂NCHNH₂PbX₃, CH₃NH₃SnX₃, or Csₐ(CH₅NH₃)_{b}(CH₃NH₃)_{c}PbI_{3(1-y)}Br_{3y} where X is a halogen which can be the same or different between or within each formula, a is about 0 to about 0.5, b is about 0 to about 0.8, c is about 0 to about 0.8, and y is about 0 to about 1.

33. The method of any of the preceding claims, wherein the PSC is a p-i-n type device.

34. The method of any of the preceding claims, wherein the PSC is an n-i-p type device.

35. The method of any of the preceding claims, wherein the perovskite layer is part of a structure that further comprises one or more of an anode; a hole transport layer (HTL); or a cathode.

36. The method of any of the preceding claims, wherein the perovskite layer is part of a structure that further comprises one or more of an anode; an electron transport layer (ETL); or a cathode.

37. The method of any of the preceding claims, wherein the method further comprises adding a cathode.

38. The method of any of the preceding claims, wherein the method further comprises adding a cathode and the method for adding the cathode is screen printing, thermal evaporation, sputtering, or atomic layer deposition.

39. The method of any of the preceding claims, wherein the method further comprises adding a cathode and the method for adding the cathode is thermal evaporation.

40. The method of any of the preceding claims, wherein the method further comprises adding a cathode and the cathode is Fe, C, Ni, Pt, Ag, Al, or Cu.

41. The method of any of the preceding claims, wherein the method further comprises adding a cathode and the cathode is Ag, Al, or Cu.

42. The method of any of the preceding claims, wherein the PSC has an open circuit voltage (Voc) of from about 0.7 V to about 1.3V.

43. The method of any of the preceding claims, wherein the PSC has fill factor (FF) of from about 35% to about 80%.

44. The method of any of the preceding claims, wherein the PSC has a current density (J_{sc}) of from about 10 mA/cm² to about 25 mA/cm².

45. The method of any of the preceding claims, wherein the PSC has a Power Conversion Efficiency (PCE) of from about 4% to about 20%.

46. The method of any of the preceding claims, wherein the PSC is a flexible PSC.

47. The PSC made according to any of the preceding claims.

48. The PSC of claim 47, comprising an anode; a hole transport layer (HTL); an electron transport layer (ETL) and a perovskite layer, prepared according to any of claims 1 to 46; and a cathode.

49. The PSC of claim 48, wherein the anode is ITO/glass or FTL/glass.

50. The PSC of claim 48 or claim 49, wherein the HTL is NiOₓ, PTAA or PTAA/PFN.

51. The PSC of any of claims 48-50, wherein the perovskite layer is one or more of CH₃NH₃PbX₃, CH₃NH₃PbI₃, H₂NCHNH₂PbX₃, or CH₃NH₃SnX₃, where X is a halogen which can be the same or different between or within each formula.

52. The PSC of any of claims 48-51, wherein the cathode is Fe, C, Ni, Pt, Ag, Al, or Cu.

53. The PSC of any of claims 48-52, wherein the cathode is Ag, Al, or Cu.

54. The PSC of claim 47, comprising an anode; an ETL; an HTL and a perovskite layer, prepared according to any of claims 1 to 46; and a cathode.

55. The PSC of claim 54, wherein the anode is ITO/glass.

56. The PSC of claim 54 or claim 55, wherein the ETL is SnO₂, TiO₂, or ZnO.

57. The PSC of any of claims 54-56, wherein the perovskite layer is one or more of CH₃NH₃PbX₃, CH₃NH₃PbI₃, H₂NCHNH₂PbX₃, or CH₃NH₃SnX₃, where X is a halogen which can be the same or different between or within each formula.

58. The PSC of any of claims 54-57, wherein the cathode is Fe, C, Ni, Pt, Ag, Al, or Cu.

59. The PSC of any of claims 54-58, wherein the cathode is Ag, Al, or Cu.
